(19) United States
(12) Patent Application Publication
(10) Pub. No.: US 2025/0318168 A1
(43) Pub. Date: Oct. 9, 2025

(54) NANOSTRUCTURE TRANSISTORS AND METHODS OF FORMING THE SAME

(71) Applicant: Taiwan Semiconductor Manufacturing Co., Ltd., Hsinchu (TW)

(72) Inventors: Chung-Wei Hsu, Baoshan Township (TW); Lung-Kun Chu, New Taipei City (TW); Shih-Hao Lai, Hsinchu (TW); Kuo-Cheng Chiang, Hsinchu (TW); Chih-Hao Wang, Baoshan Township (TW)

(21) Appl. No.: 18/799,191

(22) Filed: Aug. 9, 2024

Related U.S. Application Data
(60) Provisional application No. 63/575,070, filed on Apr. 5, 2024.

(51) Int. Cl. H01L 29/66; H01L 21/02; H01L 27/092; H01L 29/06; H01L 29/08; H01L 29/423; H01L 29/775; H01L 29/786

(52) U.S. Cl. CPC H10D 30/014; H01L 21/02634; H10D 62/116; H10D 62/151; H10D 64/015; H01L 21/02532; H10D 30/43; H10D 30/6735; H10D 30/6757; H10D 62/121; H10D 84/85

(57) ABSTRACT

A method includes forming a stack of nanostructures over a substrate; forming a recess in the substrate adjacent the stack of nanostructures, wherein the recess exposes sidewalls of the stack of nanostructures; depositing a continuous semiconductor seed layer in the recess and extending along the sidewalls of the stack of nanostructures; epitaxially growing a source/drain region on the semiconductor seed layer; after epitaxially growing the source/drain region, forming inner spacers between adjacent nanostructures of the stack of nanostructures; and forming a gate structure between adjacent nanostructures of the stack of nanostructures.

### PRIORITY CLAIM AND CROSS-REFERENCE

This application claims the benefit of U.S. Provisional Application No. 63/575,070, filed on Apr. 5, 2024, which application is hereby incorporated herein by reference

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a nanostructure field-effect transistor (nano-FET) in a three-dimensional view, in accordance with some embodiments.

FIGS. 2, 3, 4, 5, 6, 7, 8A, 8B, 8C, 9A, 9B, 9C, 10, 11, 12A, 12B, 12C, 13A, 13B, 13C, 14A, 14B, 14C, 15A, 15B, 15C, 16A, 16B, 16C, 17A, 17B, 17C, 18A, 18B, 18C, 19A, 19B, 19C, 20A, 20B, 20C, 21A, 21B, 21C, 22A, 22B, and 22C are views of intermediate stages in the manufacturing of nano-FETs, in accordance with some embodiments.

FIGS. 23A, 23B, 23C, 23D, and 23E are magnified views of a portion of a nano-FET, in accordance with some embodiments.

FIG. 24 is a view of an intermediate stage in the manufacturing of nano-FETs, in accordance with some embodiments.

FIGS. 25, 26, 27, 28, 29, 30, 31, and 32 are views of intermediate stages in the manufacturing of nano-FETs, in accordance with some embodiments.

FIG. 33 is a magnified view of a portion of a nano-FET, in accordance with some embodiments.

FIG. 34 is a view of an intermediate stage in the manufacturing of nano-FETs, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, the source/drain regions of nanostructure-FETs are formed on a continuous seed layer. Forming the source/drain regions on the seed layer can reduce defects within the source/drain regions and improve uniformity of the source/drain regions. To facilitate formation of the seed layer, inner spacers of the nanostructure-FETs are formed after the source/drain regions have been formed. In some cases, a hard mask is formed to protect the nanostructures of the nanostructure-FETs. The use of a seed layer as described herein can increase device performance, density and yield.

Embodiments are described below in a particular context, a die comprising nanostructure field-effect transistors (e.g., “nanostructure-FETs” or “nano-FETs”). Various embodiments may be applied, however, to dies comprising other types of transistors (e.g., fin field-effect transistors (FinFETs), planar transistors, or the like) in lieu of or in combination with the nanostructure-FETs.

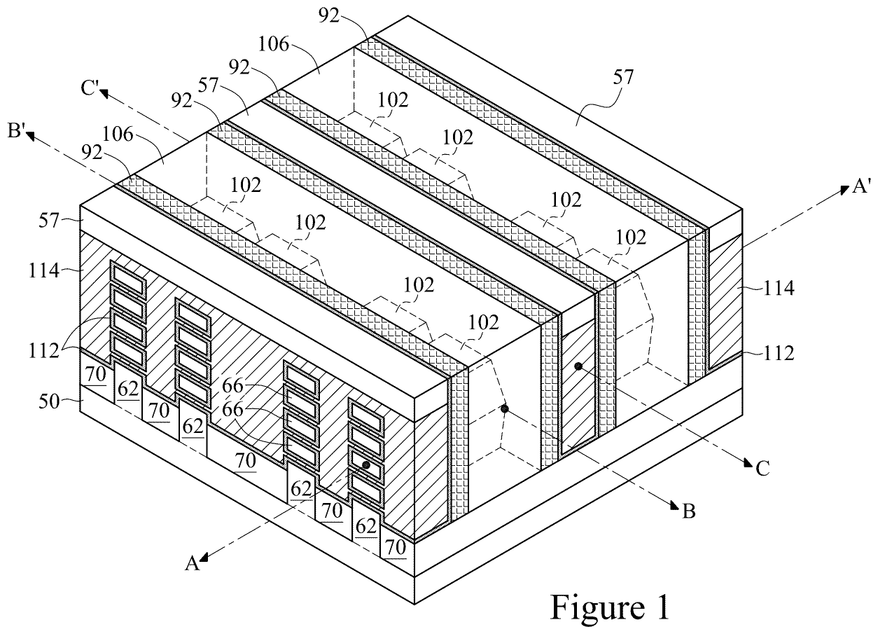

FIG. 1 illustrates an example of nanostructure-FETs (e.g., nanowire FETs, nanosheet FETs, nano-FETs), gate-all-around (GAA) FETs, or the like, in a three-dimensional view, in accordance with some embodiments. Some features of the nanostructure-FETs may be omitted from FIG. 1 for clarity. The nanostructure-FETs include nanostructures 66 (e.g., nanosheets, nanowires, or the like) over fins 62 on a substrate 50 (e.g., a semiconductor substrate), with the nanostructures 66 being semiconductor features that act as channel regions for the nanostructure-FETs. The nanostructures 66 may include p-type nanostructures, n-type nanostructures, or a combination thereof. Isolation regions 70, such as shallow trench isolation (STI) regions, are disposed between adjacent fins 62, which may protrude above and from between neighboring isolation regions 70. The nanostructures 66 are disposed over and between adjacent isolation regions 70. Although the isolation regions 70 are described/illustrated as being separate from the substrate 50, as used herein, the term “substrate” may refer to the semiconductor substrate alone or a combination of the semiconductor substrate and the isolation regions. Additionally, although a bottom portion of the fins 62 are illustrated as being single, continuous materials with the substrate 50, the bottom portion of the fins 62 and/or the substrate 50 may comprise a single material or a plurality of materials. In this context, the fins 62 refer to the portion extending between the neighboring isolation regions 70.

Gate dielectrics 112 are over top surfaces of the fins 62 and along top surfaces, sidewalls, and bottom surfaces of the nanostructures 66. Gate electrodes 114 are over the gate dielectrics 112. Source/drain regions 102 are disposed on the fins 62 at opposing sides of the gate dielectrics 112 and the gate electrodes 114. Source/drain region(s) 102 may refer to a source or a drain, individually or collectively dependent upon the context. An inter-layer dielectric (ILD) 106 is formed over the source/drain regions 102. Contacts (subsequently described) to the source/drain regions 102 will be formed through the ILD 106. In some embodiments, the source/drain regions 102 may be shared between various nanostructures 66.

FIG. 1 further illustrates reference cross-sections that are used in later figures. Cross-section A-A′ is along a longitudinal axis of a fin 62 of a nanostructure-FET and in a direction of, for example, a current flow between the source/drain regions 102 of the nanostructure-FET. Cross-section B-B′ is perpendicular to cross-section A-A′ and extends through source/drain regions 102 of the nanostructure-FETs. Cross-section C-C′ is parallel to cross-section B-B′ and along a longitudinal axis of a gate electrode 114. Subsequent figures refer to these reference cross-sections for clarity.

Some embodiments discussed herein are discussed in the context of nanostructure-FETs formed using a gate-last process. In other embodiments, a gate-first process may be used. Also, some embodiments contemplate aspects used in planar devices, such as planar FETs, or in fin field-effect transistors (FinFETs), in lieu of or in combination with the nanostructure-FETs. For example, FinFETs may include semiconductor fins on a substrate, with the semiconductor fins being semiconductor features which act as channel regions for the FinFETs. Similarly, planar FETs may include a substrate, with planar portions of the substrate being semiconductor features which act as channel regions for the planar FETs.

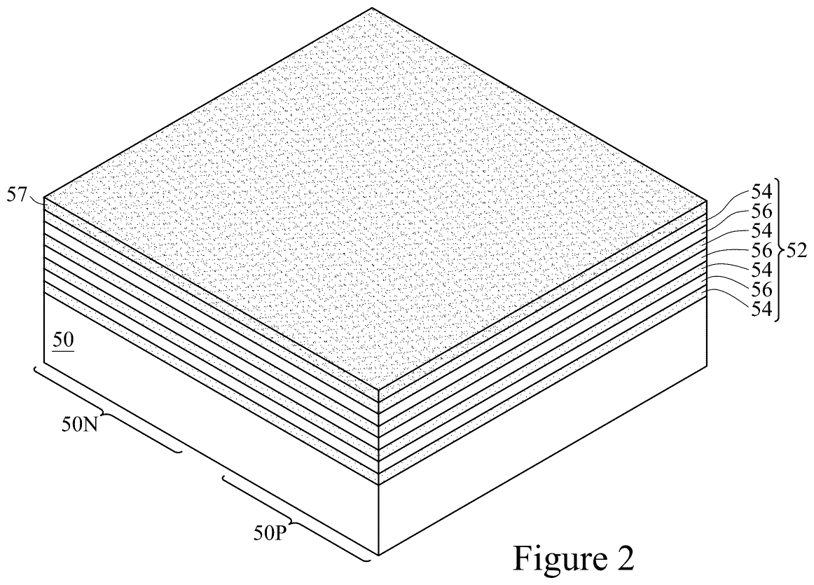

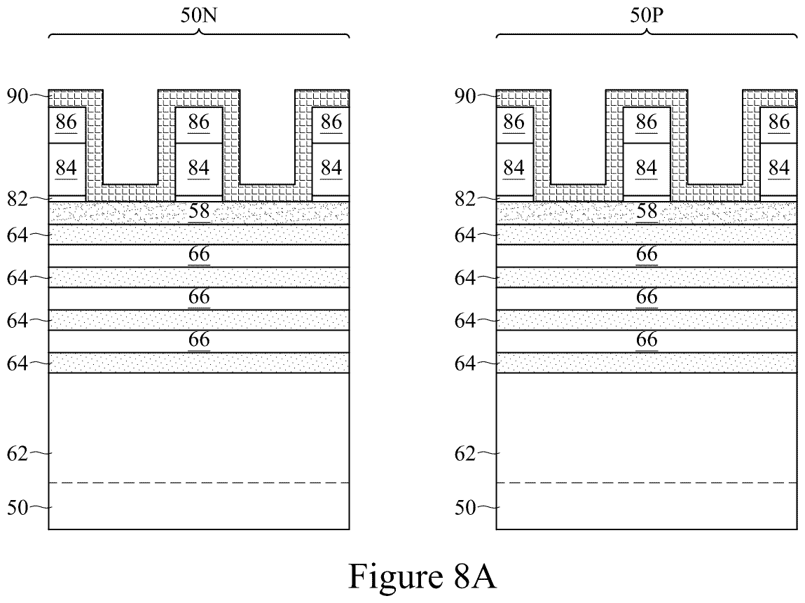

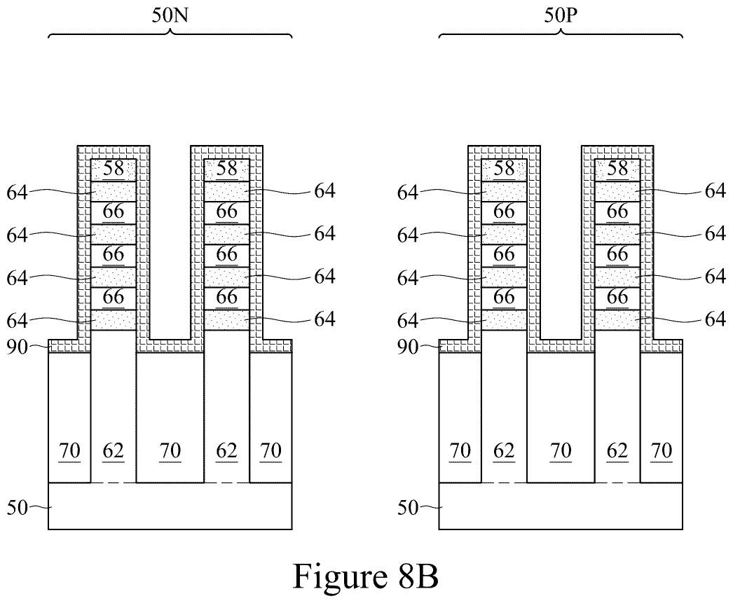

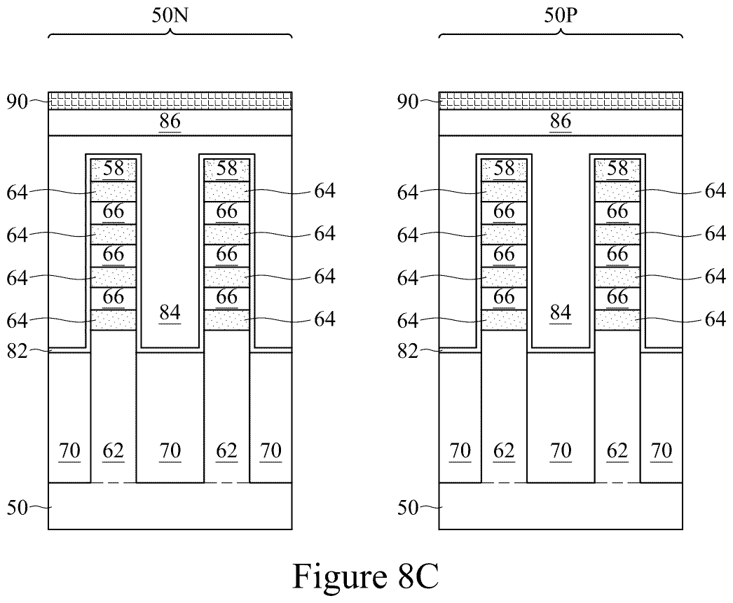

FIGS. 2-22C are views of intermediate stages in the manufacturing of nanostructure-FETs, in accordance with some embodiments. FIGS. 2, 3, 4, 5, 6, and 7 are three-dimensional views showing a similar three-dimensional view as FIG. 1. FIGS. 8A, 9A, 10, 11, 12A, 13A, 14A, 15A, 16A, 17A, 18A, 19A, 20A, 21A, and 22A illustrate cross-sectional views along a similar cross-section as reference cross-section A-A′ in FIG. 1. FIGS. 8B, 9B, 12B, 13B, 14B, 15B, 16B, 17B, 18 B, 19B, 20B, 21B, and 22B illustrate cross-sectional views along a similar cross-section as reference cross-section B-B′ in FIG. 1. FIGS. 8C, 9C, 12C, 13C, 14C, 15C, 16C, 17C, 18C, 19C, 20C, 21C, and 22C illustrate cross-sectional views along a similar cross-section as reference cross-section C-C′ in FIG. 1.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof.

As shown in FIG. 2, the substrate 50 has an n-type region 50N and a p-type region 50P. The n-type region 50N can be for forming n-type devices, such as NMOS transistors, e.g., n-type nanostructure-FETs, and the p-type region 50P can be for forming p-type devices, such as PMOS transistors, e.g., p-type nanostructure-FETs. The n-type region 50N may (or may not) be physically separated (not separately illustrated) from the p-type region 50P, and any number of device features (e.g., other active devices, doped regions, isolation structures, etc.) may be disposed between the n-type region 50N and the p-type region 50P. Although one n-type region 50N and one p-type region 50P are illustrated, any number of n-type regions 50N and p-type regions 50P may be present.

Further in FIG. 2, a multi-layer stack 52 is formed over the substrate 50. The multi-layer stack 52 includes alternating first semiconductor layers 54 and second semiconductor layers 56. The first semiconductor layers 54 are formed of a first semiconductor material, and the second semiconductor layers 56 are formed of a second semiconductor material. The semiconductor materials may each be selected from the candidate semiconductor materials of the substrate 50.

In the illustrated embodiment, and as subsequently described in greater detail, the first semiconductor layers 54 will be removed and the second semiconductor layers 56 will patterned to form channel regions (e.g., nanostructures 66) for the nanostructure-FETs in both the n-type region 50N and the p-type region 50P. In such embodiments, the channel regions in both the n-type region 50N and the p-type region 50P may have a same material composition (e.g., silicon or another semiconductor material) and be formed simultaneously. The first semiconductor layers 54 are dummy layers that will be removed in subsequent processing to expose top surfaces and bottom surfaces of the second semiconductor layers 56. The first semiconductor material of the first semiconductor layers 54 is a material that has a high etching selectivity from the etching of the second semiconductor layers 56, such as silicon germanium. The second semiconductor material of the second semiconductor layers 56 is a material suitable for both n-type and p-type devices, such as silicon.

In another embodiment (not separately illustrated), the first semiconductor layers 54 will be patterned to form channel regions for nanostructure-FETs in one region (e.g., the p-type region 50P), and the second semiconductor layers 56 will be patterned to form channel regions for nanostructure-FETs in another region (e.g., the n-type region 50N). The first semiconductor material of the first semiconductor layers 54 may be a material suitable for p-type devices, such as silicon germanium (e.g., SiₓGe₁₋ₓ, where x can be in the range of o to 1), pure germanium, a III-V compound semiconductor, a II-VI compound semiconductor, or the like. The second semiconductor material of the second semiconductor layers 56 may be a material suitable for n-type devices, such as silicon, silicon carbide, a III-V compound semiconductor, a II-VI compound semiconductor, or the like. The first semiconductor material and the second semiconductor material may have a high etching selectivity from the etching of one another, so that the first semiconductor layers 54 may be removed without significantly removing the second semiconductor layers 56 in the n-type region 50N, and the second semiconductor layers 56 may be removed without significantly removing the first semiconductor layers 54 in the p-type region 50P.

The multi-layer stack 52 is illustrated as including four of the first semiconductor layers 54 and three of the second semiconductor layers 56. It should be appreciated that the multi-layer stack 52 may include any number of the first semiconductor layers 54 and the second semiconductor layers 56. Each of the layers of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like. In some embodiments, some layers of the multi-layer stack 52 are formed to be thinner than other layers of the multi-layer stack 52.

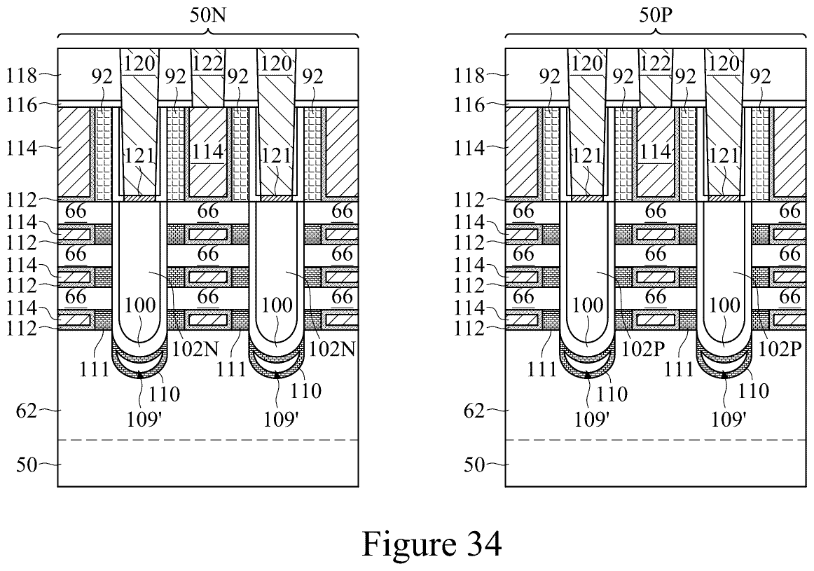

Still referring to FIG. 2, a hard mask layer 57 may be formed over the multi-layer stack 52, in accordance with some embodiments. The hard mask layer 57 may comprise a dielectric material such as silicon nitride, silicon carbonitride, silicon oxycarbonitride, silicon oxynitride, the like, or a combination thereof. In some embodiments, the hard mask layer 57 may comprise multiple layers of different materials. The hard mask layer 57 may have at thickness in the range of about 1 nm to about 10 nm, though other thicknesses are possible. In other embodiments, the hard mask layer 57 is not formed (e.g., see FIG. 34).

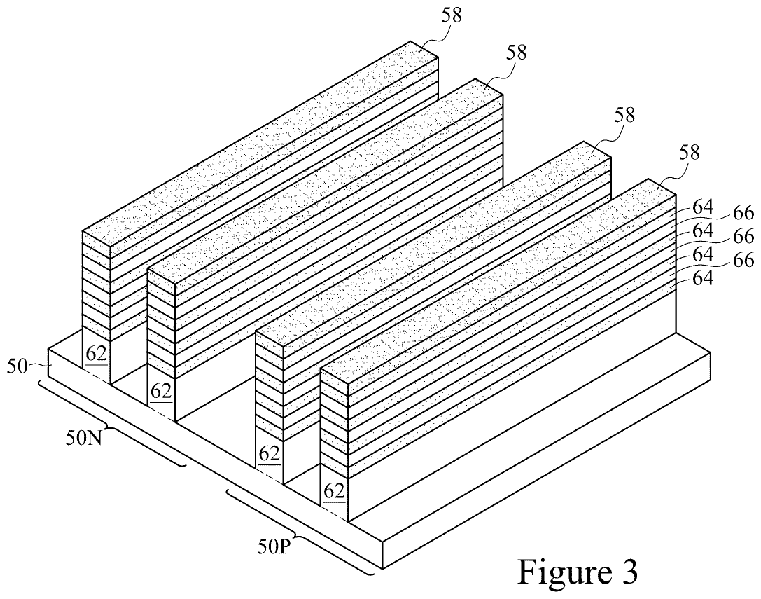

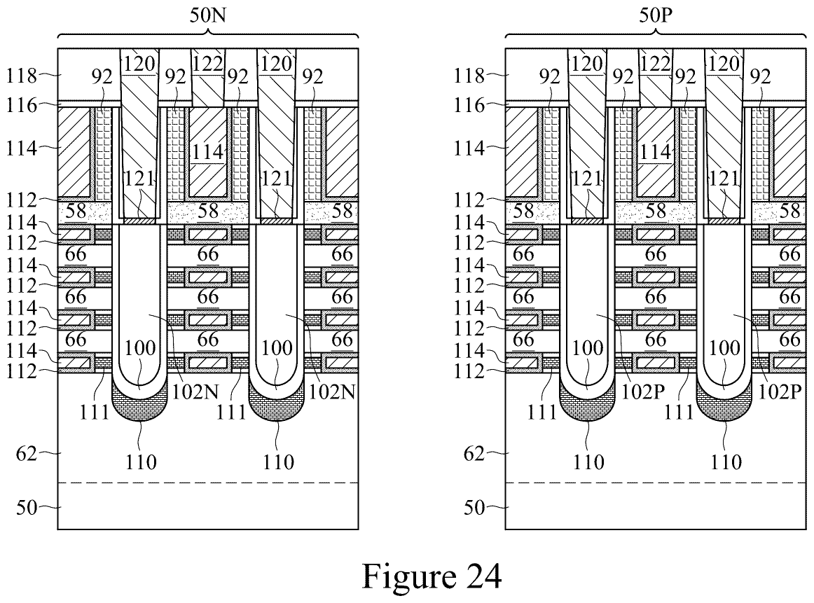

In FIG. 3, fins 62 are formed in the substrate 50, and nanostructures 64 and nanostructures 66 (collectively referred to as “nanostructures 64/66”) are formed in the multi-layer stack 52. In some embodiments, the nanostructures 64/66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64/66 by etching the multi-layer stack 52 may further define first nanostructures 64 from the first semiconductor layers 54 and define second nanostructures 66 from the second semiconductor layers 56. As shown in FIG. 3, the hard mask layer 57 is etched to form the hard mask 58. In some embodiments, the hard mask 58 is present in the final nanostructure-FET device (e.g., see FIG. 24).

The fins 62, the nanostructures 64/66, and the hard mask 58 may be patterned by any suitable method. For example, the fins 62, the nanostructures 64/66, and the hard mask 58 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64/66. In some embodiments, the hard mask layer 57 may be patterned using some or all of the same steps used to pattern the fins 62 and/or the nanostructures 64/66. In some embodiments, the hard mask 58 is patterned first, and then the hard mask 58 is used as an etch mask to pattern the nanostructures 64/66 and/or the fins 62.

The fins 62 are shown in FIG. 3 as having approximately equal widths in both the n-type region 50N and the p-type region 50P. In some embodiments, a width of the fins 62 in the n-type region 50N may be greater or less than a width of the fins 62 in the p-type region 50P. Further, while each of the fins 62, the nanostructures 64/66, and the hard mask 58 are illustrated as having an approximately constant width throughout, in other embodiments, the fins 62 and/or the nanostructures 64/66 may have tapered sidewalls such that a width of each of the fins 62 and/or the nanostructures 64/66 continuously increases in a direction towards the substrate 50. In such embodiments, each of the nanostructures 64/66 may have a different width and may be trapezoidal in shape.

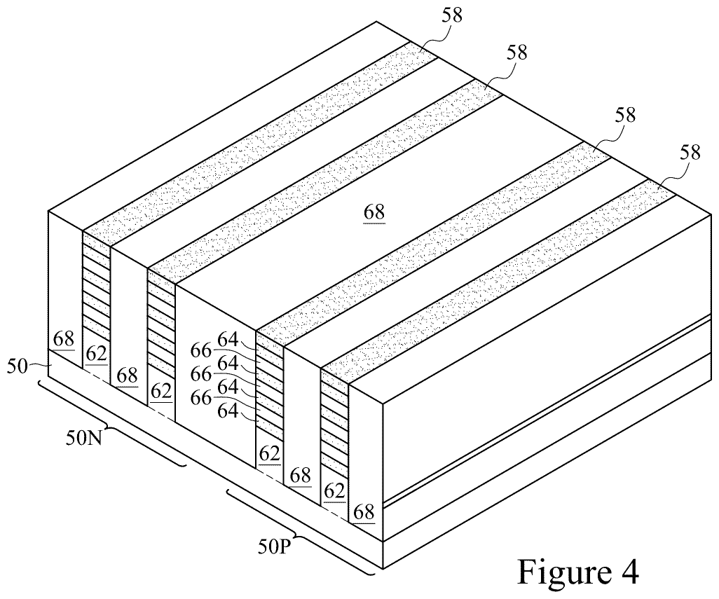

In FIG. 4, an insulation material 68 is formed over the substrate 50 and between adjacent fins 62, between adjacent nanostructures 64/66, and between adjacent regions of the hard mask 58. The insulation material 68 may be an oxide, such as silicon oxide, a nitride, the like, or a combination thereof, and may be formed by high-density plasma CVD (HDP-CVD), flowable CVD (FCVD), the like, or a combination thereof. Other insulation materials formed by any acceptable process may be used. In some embodiments, the insulation material 68 includes silicon oxide formed by an FCVD process. An annealing process may be performed once the insulation material 68 is formed. Although the insulation material 68 is illustrated as a single layer, some embodiments may utilize multiple layers. For example, in some embodiments a liner (not separately illustrated) may first be formed along a surface of the substrate 50, the fins 62, the nanostructures 64/66, and the hard mask 58. Thereafter, a fill material, such as one of the previously described insulation materials may be formed over the liner.

The insulation material 68 may be deposited over the fins 62, nanostructures 64/66, and hard mask 58 such that excess insulation material 68 covers the hard mask 58. A removal process is then applied to the insulation material 68 to remove excess insulation material 68 over the hard mask 58. In some embodiments, a planarization process such as a chemical mechanical polish (CMP), an etch-back process, combinations thereof, or the like may be utilized. The planarization process exposes the hard mask 58 such that top surfaces of the hard mask 58 and the insulation material 68 are level after the planarization process is complete.

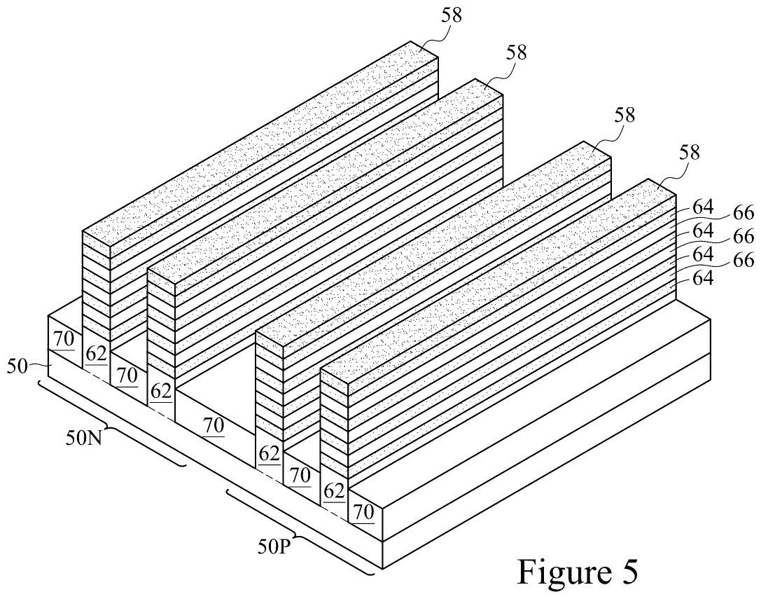

In FIG. 5, the insulation material 68 is recessed to form STI regions 70. The STI regions 70 are adjacent the fins 62. The insulation material 68 is recessed such that upper portions of fins 62, the nanostructures 64/66, and/or the hard mask 58 protrude from between neighboring STI regions 70. The upper portions of the fins 62, the nanostructures 64/66, and/or the hard mask 58 are above the STI regions 70. Further, the top surfaces of the STI regions 70 may have a flat surface as illustrated, a convex surface, a concave surface (such as dishing), or a combination thereof. The top surfaces of the STI regions 70 may be formed flat, convex, and/or concave by an appropriate etch. The STI regions 70 may be recessed using an acceptable etching process, such as one that is selective to the material of the insulation material 68 (e.g., etches the material of the insulation material 68 at a faster rate than the materials of the fins 62 and the nanostructures 64/66). For example, an oxide removal using, for example, dilute hydrofluoric (dHF) acid may be used.

The previously described process is just one example of how the fins 62 and the nanostructures 64/66 may be formed. In some embodiments, the fins 62 and/or the nanostructures 64/66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62 and/or the nanostructures 64/66. The epitaxial structures may comprise the previously described alternating semiconductor materials, such as the first semiconductor materials and the second semiconductor materials. In some embodiments in which epitaxial structures are epitaxially grown, the epitaxially grown materials may be in situ doped during growth, which may obviate prior and/or subsequent implantations, although in situ and implantation doping may be used together.

Further, appropriate wells (not separately illustrated) may be formed in the fins 62, the nanostructures 64/66, and/or the STI regions 70. In embodiments with different well types, different implant steps for the n-type region 50N and the p-type region 50P may be achieved using a photoresist or other mask (not separately illustrated). For example, a photoresist may be formed over the fins 62, the nanostructures 64/66, and the STI regions 70 in the n-type region 50N and the p-type region 50P. The photoresist is patterned to expose the p-type region 50P. The photoresist can be formed by using a spin-on technique and can be patterned using acceptable photolithography techniques. Once the photoresist is patterned, an n-type impurity implant is performed in the p-type region 50P, and the photoresist may act as a mask to substantially prevent n-type impurities from being implanted into the n-type region 50N. The n-type impurities may be phosphorus, arsenic, antimony, or the like implanted in the region to a concentration in a range from about 10¹³ atoms/cm³ to about 10¹⁴ atoms/cm³. After the implant, the photoresist is removed, such as by an acceptable ashing process.

Following or prior to the implanting of the p-type region 50P, a photoresist or other mask (not separately illustrated) is formed over the fins 62, the nanostructures 64/66, and the STI regions 70 in the p-type region 50P and the n-type region 50N. The photoresist is patterned to expose the n-type region 50N. The photoresist can be formed by using a spin-on technique and can be patterned using acceptable photolithography techniques. Once the photoresist is patterned, a p-type impurity implant may be performed in the n-type region 50N, and the photoresist may act as a mask to substantially prevent p-type impurities from being implanted into the p-type region 50P. The p-type impurities may be boron, boron fluoride, indium, or the like implanted in the region to a concentration in a range from about 10¹³ atoms/cm³ to about 10¹⁴ atoms/cm³. After the implant, the photoresist may be removed, such as by an acceptable ashing process.

After the implants of the n-type region 50N and the p-type region 50P, an anneal may be performed to repair implant damage and to activate the p-type and/or n-type impurities that were implanted. In some embodiments, the grown materials of epitaxial fins may be in situ doped during growth, which may obviate the implantations, although in situ and implantation doping may be used together.

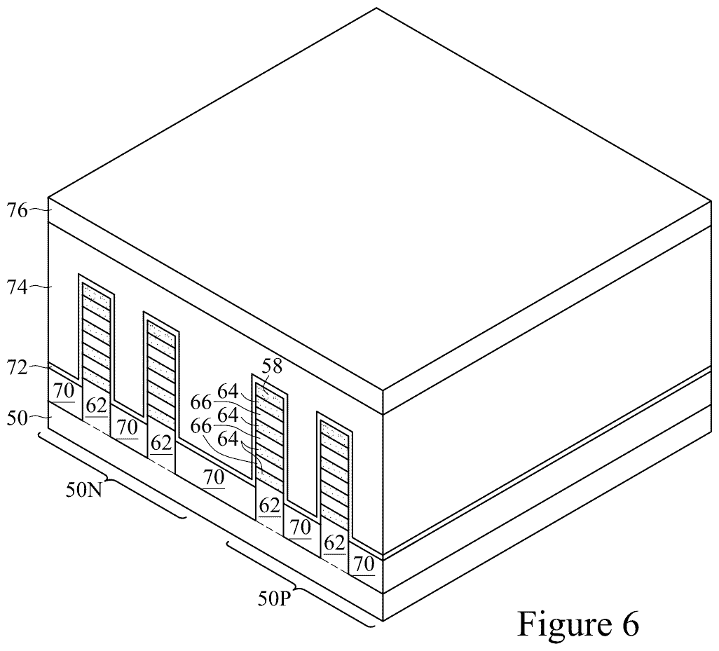

In FIG. 6, a dummy dielectric layer 72 is formed on the fins 62, the nanostructures 64/66, and/or the hard mask 58. The dummy dielectric layer 72 may be formed of silicon oxide, silicon nitride, a combination thereof, or the like, which may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The dummy gate layer 74 may be formed of a conductive or non-conductive material and may be selected from a group including amorphous silicon, polycrystalline silicon (polysilicon), poly-crystalline silicon germanium (poly-SiGe), metallic nitrides, metallic silicides, metallic oxides, and metals. The material of the dummy gate layer 74 may be deposited by CVD, physical vapor deposition (PVD), sputter deposition, or other techniques for depositing the selected material. The dummy gate layer 74 may be formed of other materials that have a high etching selectivity from the etching of insulation materials, e.g., the STI regions 70 and/or the dummy dielectric layer 72. The mask layer 76 may be deposited over the dummy gate layer 74. The mask layer 76 may be formed of a dielectric material such as silicon nitride, silicon oxynitride, or the like. In this example, a single dummy gate layer 74 and a single mask layer 76 are formed across the n-type region 50N and the p-type region 50P. In the illustrated embodiment, the dummy dielectric layer 72 covers the STI regions 70, such that the dummy dielectric layer 72 extends between the dummy gate layer 74 and the STI regions 70. In another embodiment, the dummy dielectric layer 72 covers only the fins 62, the nanostructures 64/66, and/or the hard mask 58.

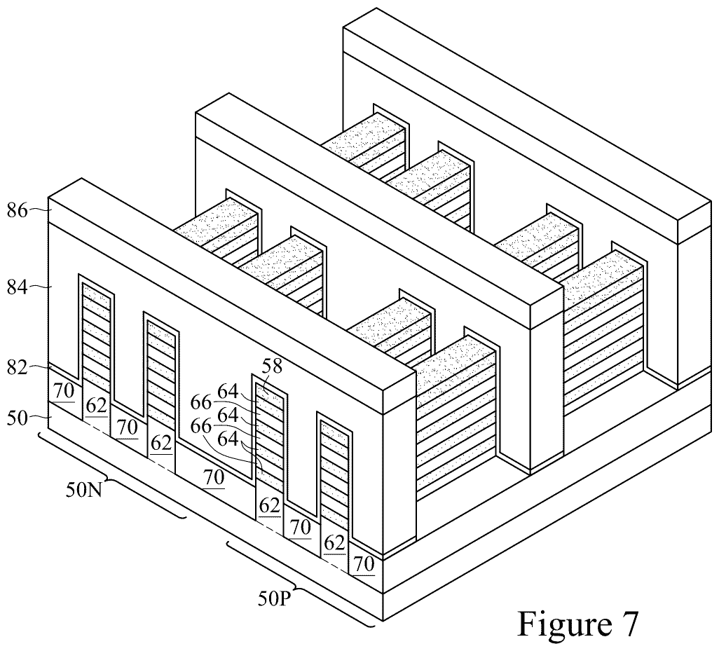

In FIG. 7, the mask layer 76 is patterned using acceptable photolithography and etching techniques to form masks 86. The pattern of the masks 86 then may be transferred to the dummy gate layer 74 and to the dummy dielectric layer 72 to form dummy gates 84 and dummy dielectrics 82, respectively. The dummy gates 84 cover respective channel regions of the nanostructures 64/66. The pattern of the masks 86 may be used to physically separate each of the dummy gates 84 from adjacent dummy gates 84. The dummy gates 84 may also have a lengthwise direction substantially perpendicular to the lengthwise direction of respective fins 62. The masks 86 can optionally be removed after patterning, such as by any acceptable etching technique. The dummy dielectrics 82 and dummy gates 84 may be considered a “dummy gate structure.”

In FIGS. 8A-8C, a spacer layer 90 is conformally formed over the nanostructures 64/66 and the STI regions 70, on exposed sidewalls of the masks 86 (if present), the dummy gates 84, the dummy dielectrics 82, the hard mask 58, the nanostructures 64/66, and the fins 62. The spacer layer 90 may be formed of one or more dielectric material(s). FIGS. 8A-8C show a spacer layer 90 formed of a single layer of dielectric material, but in other embodiments the spacer layer 90 may be formed of two or more layers of dielectric materials. Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other insulation materials formed by any acceptable process may be used. The spacer layer 90 is subsequently etched to form spacers.

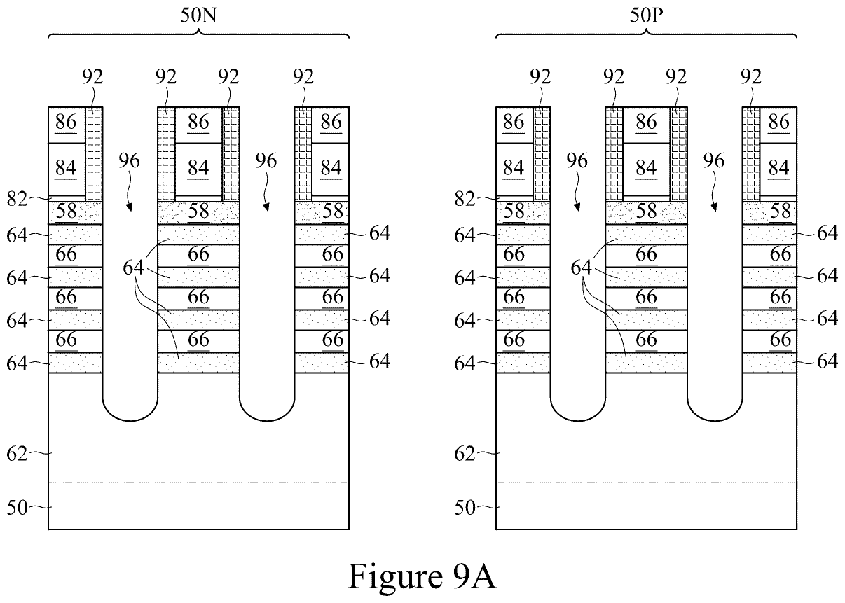

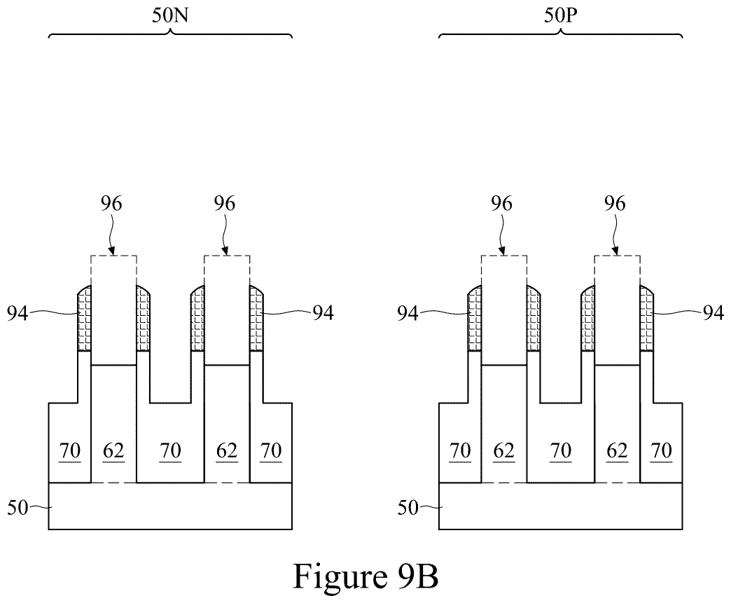

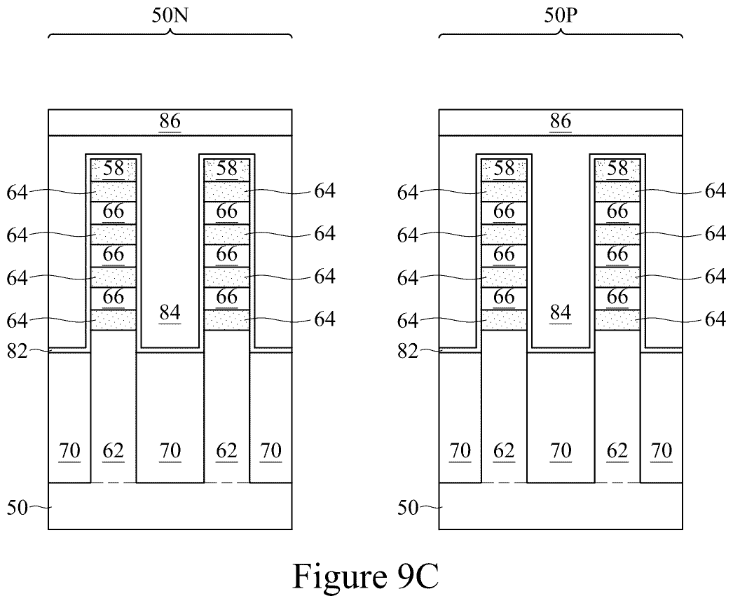

In FIGS. 9A-9C, the spacer layer 90 is patterned to form gate spacers 92 and fin spacers 94. Any acceptable etch process, such as a dry etch, a wet etch, the like, or a combination thereof, may be performed to pattern the spacer layer 90. The etching may be anisotropic. The spacer layer 90, when etched, has portions left on the sidewalls of the dummy gates 84 (thus forming the gate spacers 92) and has portions left on the sidewalls of the fins 62 and/or the nanostructures 64/66 (thus forming the fin spacers 94). After etching, the fin spacers 94 and/or the gate spacers 92 can have straight sidewalls or can have curved sidewalls. Additionally, the STI regions 70 may also be etched when patterning the spacer layer 90. The etching may recess portions of the STI regions 70 between the fins 62.

Further, implants for lightly doped source/drain (LDD) regions (not separately illustrated) may be performed. In embodiments with different device types, similar to the implants for the previously described wells, a mask, such as a photoresist, may be formed over the n-type region 50N, while exposing the p-type region 50P, and appropriate type (e.g., p-type) impurities may be implanted into the fins 62 and the nanostructures 64/66 exposed in the p-type region 50P. The mask may then be removed. Subsequently, a mask, such as a photoresist, may be formed over the p-type region 50P while exposing the n-type region 50N, and appropriate type impurities (e.g., n-type) may be implanted into the fins 62 and the nanostructures 64/66 exposed in the n-type region 50N. The mask may then be removed. The n-type impurities may be the any of the n-type impurities previously discussed, and the p-type impurities may be the any of the p-type impurities previously discussed. The lightly doped source/drain regions may have a concentration of impurities in a range from about 10¹⁵ atoms/cm³ to about 10¹⁹ atoms/cm³. An anneal may be used to repair implant damage and to activate the implanted impurities.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like. Furthermore, the n-type devices and the p-type devices may be formed using different structures and steps.

Still referring to FIGS. 9A-9C, source/drain recesses 96 are patterned in the hard mask 58, the fins 62, the nanostructures 64/66, and the substrate 50, in accordance with some embodiments. Epitaxial source/drain regions are subsequently formed in the source/drain recesses 96. The source/drain recesses 96 may extend through the nanostructures 64/66 and into the substrate 50. In some embodiments, the fins 62 may be etched such that bottom surfaces of the source/drain recesses 96 are disposed below the top surfaces of the STI regions 70. The source/drain recesses 96 may be formed by etching the hard mask 58, the fins 62, the nanostructures 64/66, and the substrate 50 using anisotropic etching processes, such as RIE, NBE, or the like. In some embodiments, the gate spacers 92 and the dummy gates 84 mask portions of the hard mask 58, the fins 62, the nanostructures 64/66, and the substrate 50 during the etching processes used to form the source/drain recesses 96. A single etch process or multiple etch processes may be used to etch each layer of the hard mask 58, the nanostructures 64/66 and/or the fins 62. Timed etch processes may be used to stop the etching of the source/drain recesses 96 after the source/drain recesses 96 reach a desired depth.

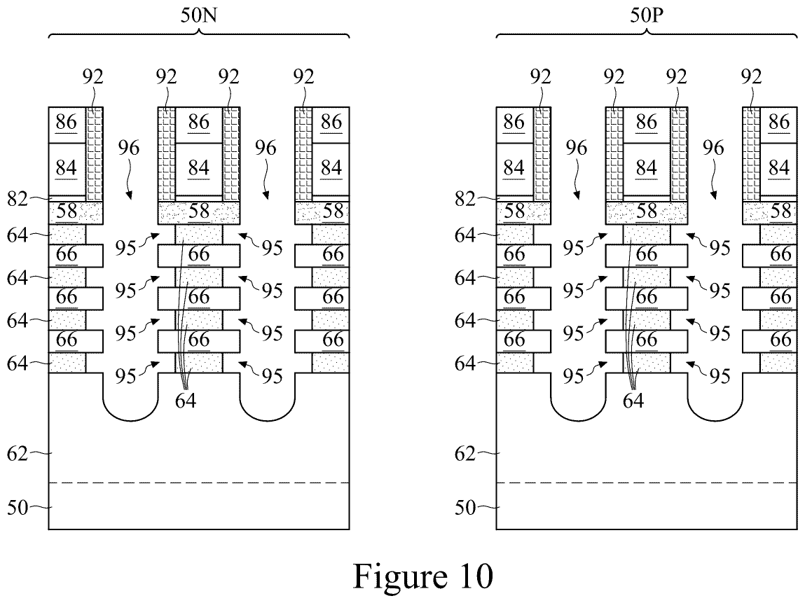

In FIG. 10, the source/drain recesses 96 are laterally expanded to form sidewall recesses 95 in the first nanostructures 64, in accordance with some embodiments. Specifically, portions of the sidewalls of the first nanostructures 64 exposed by the source/drain recesses 96 may be recessed to form sidewall recesses 95. Accordingly, a sidewall recess 95 may have a height that is about the same as a height (e.g., a thickness) of its corresponding first nanostructure 64. The sidewalls of the first nanostructures 64 may be recessed a lateral distance in the range of about 1 nm to about 15 nm to form the sidewall recesses 95, though other distances are possible. Although sidewalls of the first nanostructures 64 within the sidewall recesses 95 are illustrated as being flat, the sidewalls may be concave or convex. The sidewalls may be recessed using any acceptable etch process, such as one that is selective to the material of the first nanostructures 64 (e.g., selectively etches the material of the first nanostructures 64 at a faster rate than the material of the second nanostructures 66). The etching may be isotropic or anisotropic. For example, when the second nanostructures 66 are formed of silicon and the first nanostructures 64 are formed of silicon germanium, the etch process may be a wet etch using tetramethylammonium hydroxide (TMAH), ammonium hydroxide (NH₄OH), or the like. In another embodiment, the etch process may be a dry etch using a fluorine-based gas such as hydrogen fluoride (HF) gas. In some cases, the etch process may slightly recess (e.g., remove portions of) the second nanostructures 66 exposed by the sidewall recesses 95 as the sidewall recesses 95 are formed (not illustrated). In such cases, a sidewall recess 95 may have a height that is larger than the height (e.g., the thickness) of its corresponding first nanostructure 64. In some embodiments, the same etch process may be continually performed to both form the source/drain recesses 96 and recess the sidewalls of the first nanostructures 64 to form the sidewall recesses 95. In some cases, the sidewall recesses 95 may be considered part of the source/drain recesses 96.

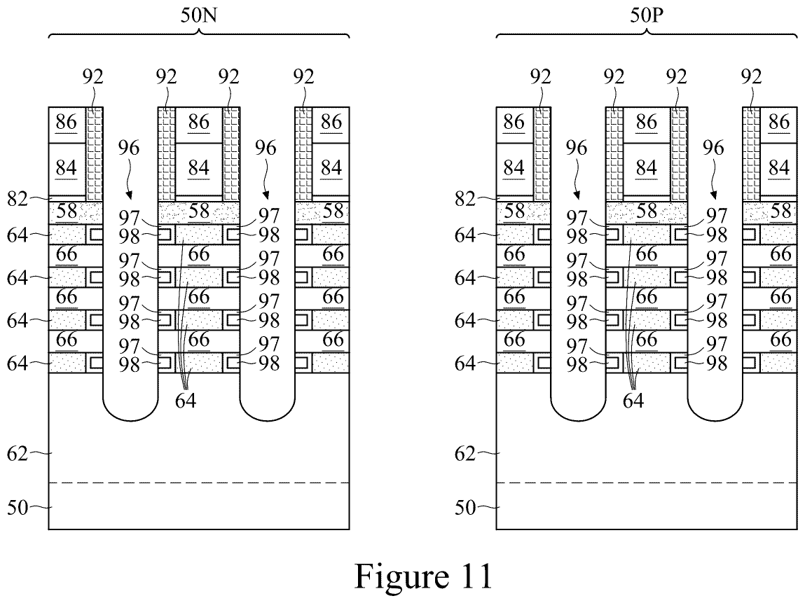

In FIG. 11, spacer liner 97 and sacrificial spacers 98 are formed in the sidewall recesses 95, in accordance with some embodiments. In other words, the spacer liner 97 and sacrificial spacers 98 are formed on the sidewalls of the remaining portions of the first nanostructures 64. As will be subsequently described in greater detail, source/drain regions are subsequently formed in the source/drain recesses 96, and the sacrificial spacers 98 are subsequently replaced with inner spacers.

In some embodiments, the spacer liner 97 is formed by conformally forming a liner material in the source/drain recesses 96 and in the sidewall recesses 95, and subsequently etching the liner material. The liner material of the spacer liner 97 may be etched after depositing the sacrificial material of the sacrificial spacers 98, described below. The spacer liner 97 may be formed on sidewalls of first nanostructures 64, on bottom surfaces of second nanostructures 66, and on top surfaces of second nanostructures 66. In some embodiments, the liner material is similar to the material of the second nanostructures 66. For example, in some embodiments, both the second nanostructures 66 and the liner material may be silicon. Other materials are possible. The liner material may be deposited using a suitable technique, such as VPE, MBE, CVD, ALD, or the like. In some embodiments, the spacer liner 97 has a thickness in the range of about 0.5 nm to about 3 nm, though other thicknesses are possible.

In some embodiments, the sacrificial spacers 98 are formed by forming a sacrificial material on the liner material in the source/drain recesses 96 and in the sidewall recesses 95, and subsequently etching the sacrificial material. The sacrificial material may fill or overfill the sidewall recesses 95. In some embodiments, the sacrificial material is similar to the material of the first nanostructures 64. For example, in some embodiments, both the first nanostructures 64 and the sacrificial material may be silicon germanium. Other materials are possible. The sacrificial material may be deposited using a suitable technique, such as VPE, MBE, CVD, ALD, or the like. An etch process is performed to remove portions of the liner material and sacrificial material to form the spacer liner 97 and sacrificial spacers 98. The etching of the liner material and sacrificial material may be anisotropic. For example, the etch process may be a dry etch such as a RIE, a NBE, or the like. After performing the etching of the insulating material, the remaining portions of the liner material and sacrificial material within the sidewall recesses 95 form the spacer liner 97 and sacrificial spacers 98, respectively.

Although outer sidewalls of the spacer liner 97 and the sacrificial spacers 98 are illustrated as being flush (e.g. approximately coplanar) with sidewalls of the second nanostructures 66, the outer sidewalls of the spacer liner 97 and the sacrificial spacers 98 may extend beyond or be recessed from sidewalls of the second nanostructures 66. In other words, the sacrificial spacers 98 may partially fill, completely fill, or overfill the sidewall recesses 95. Moreover, although the sidewalls of the sacrificial spacers 98 are illustrated as being flat, the sidewalls of the sacrificial spacers 98 may be concave or convex. Due to the presence of the spacer liner 97, a sacrificial spacer 98 may have a thickness that is less than a thickness of an adjacent first nanostructure 64.

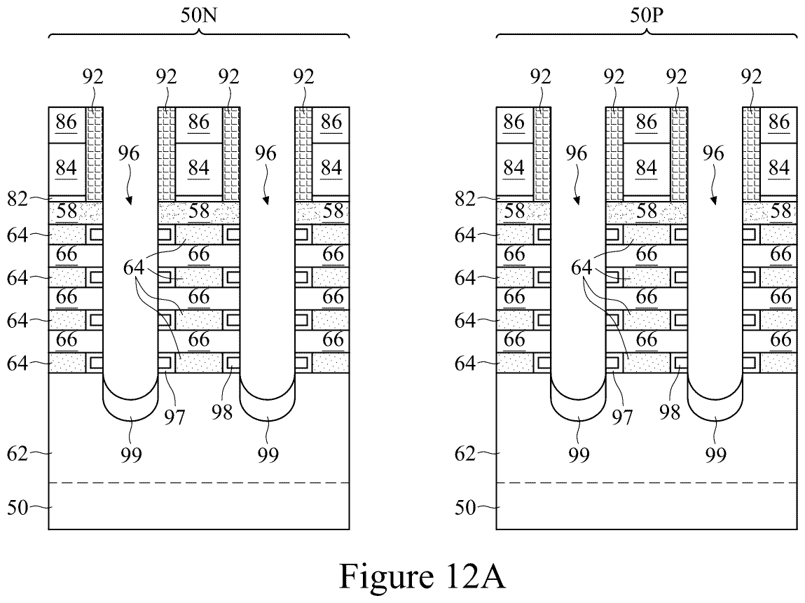

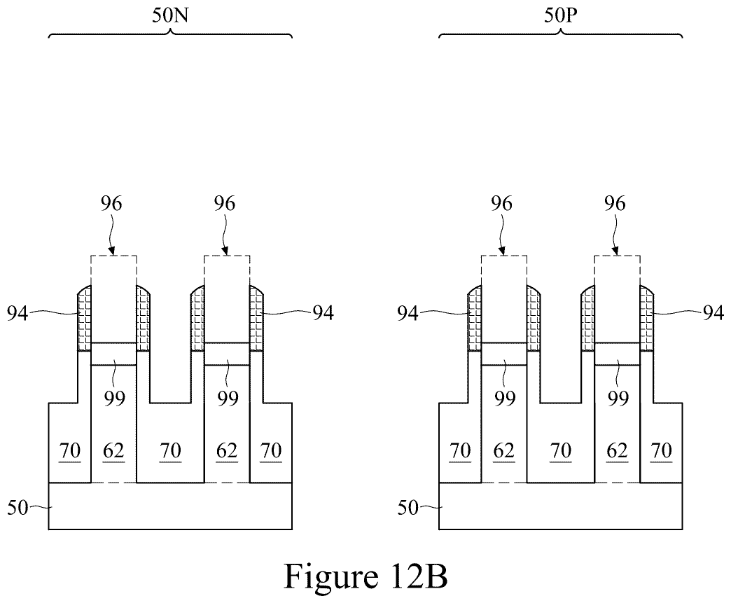

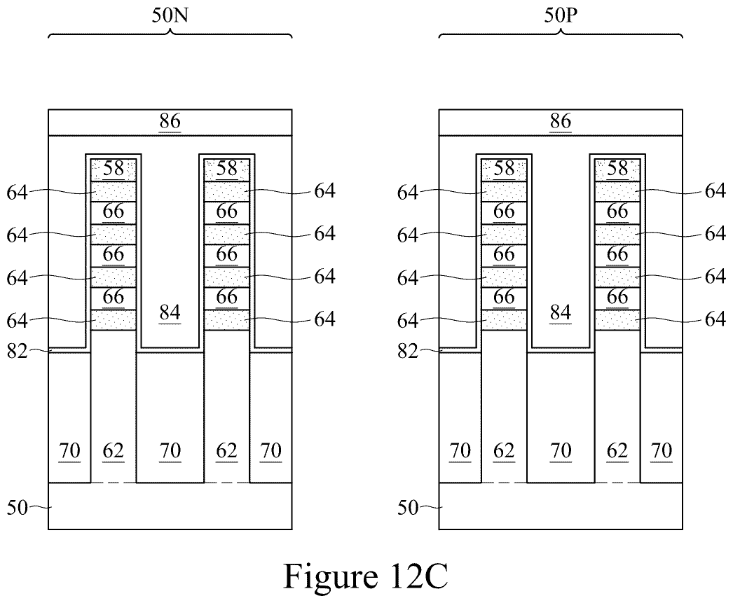

In FIGS. 12A-12C, sacrificial layers 99 are deposited in the source/drain recesses 96, in accordance with some embodiments. As shown in FIGS. 12A-12B, the sacrificial layers 99 are deposited on bottom regions of the source/drain recesses 96. The sacrificial layers 99 are formed on surfaces of the fins 62 exposed within the source/drain recesses 96. The sacrificial layers 99 may also extend on surfaces of sacrificial spacers 98, spacer liner 97, STI regions 70, and/or fin spacers 94 in some cases. In some embodiments, the material of the sacrificial layers 99 is similar to the material of the first nanostructures 64. For example, in some embodiments, both the first nanostructures 64 and the sacrificial layers 99 may be silicon germanium. Other materials are possible. The sacrificial layers 99 may be deposited using a suitable technique, such as VPE, MBE, CVD, ALD, or the like. In some embodiments, the sacrificial layers 99 may have a thickness that is in the range of about 2 nm to about 10 nm, though other thicknesses are possible.

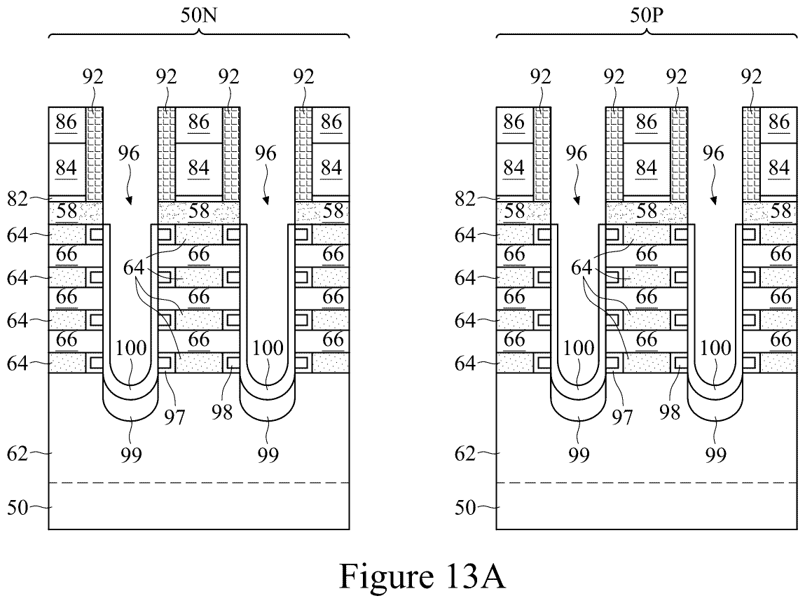

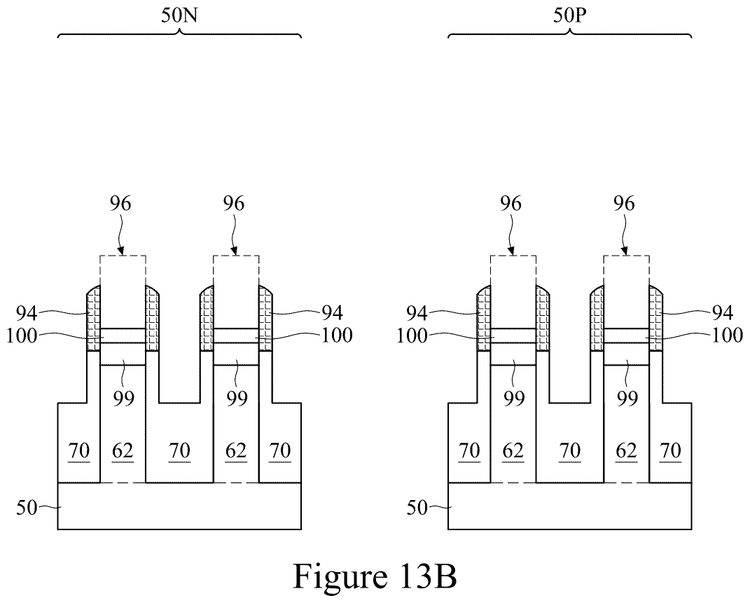

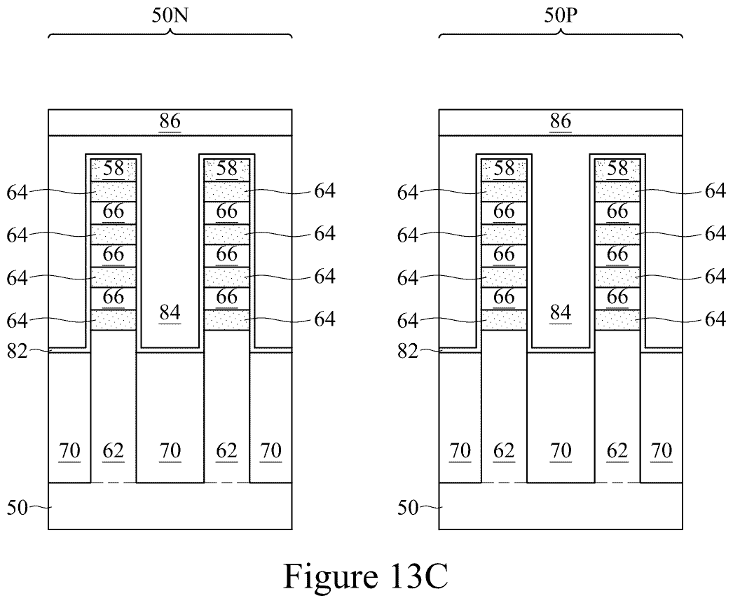

In FIGS. 13A-13C, source/drain seed layers 100 are formed in the source/drain recesses 96, in accordance with some embodiments. The source/drain regions are subsequently formed on the source/drain seed layers 100, which can allow the source/drain regions to be formed having better quality, fewer defects, more uniformity, and/or smaller volume, described in greater detail below. Each source/drain seed layer 100 may be formed as a continuous layer within a source/drain recess 96, and may cover surfaces of the second nanostructures 66, sacrificial layers 99, spacer liner 97, and sacrificial spacers 98 within the source/drain recess 96. In some embodiments, the source/drain seed layers 100 have a thickness in the range of about 0.5 nm to about 20 nm, though other thicknesses are possible. The source/drain seed layers 100 may be formed of a semiconductor material selected from the candidate semiconductor materials of the substrate 50 or may be formed of a semiconductor material similar to that of the subsequently-formed source/drain regions. For example, in some embodiments, the source/drain seed layers 100 may be formed of silicon or silicon germanium, though other materials are possible. The source/drain seed layers 100 may be doped or undoped. For example, in some embodiments, the source/drain seed layers 100 may be doped with boron or gallium, though other dopants are possible. The source/drain seed layers 100 may be in situ doped during formation or may be doped using an implantation process. The source/drain seed layers 100 may be deposited using a suitable technique, such as an epitaxial growth process, VPE, MBE, CVD, ALD, or the like. In some embodiments, the source/drain seed layers 100 in the n-type region 50N may be a different material and/or have a different doping than the source/drain seed layers 100 in the p-type region 50P.

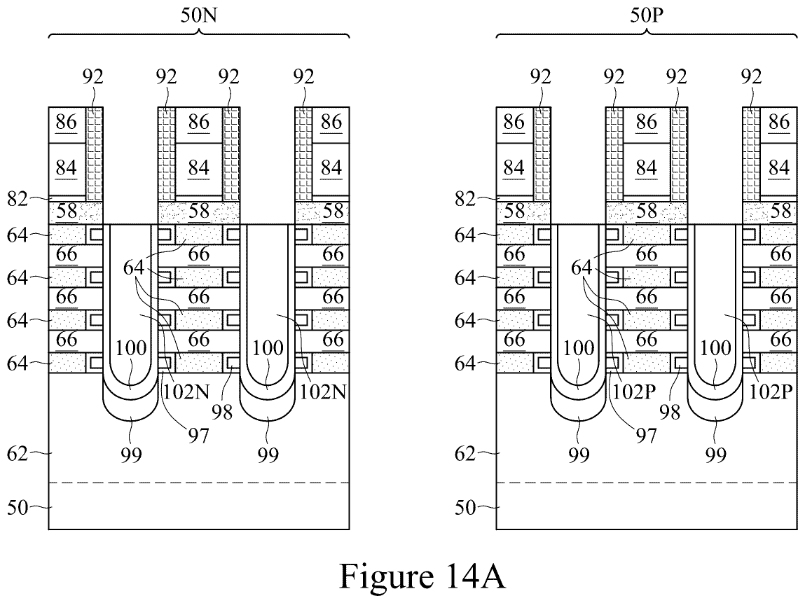

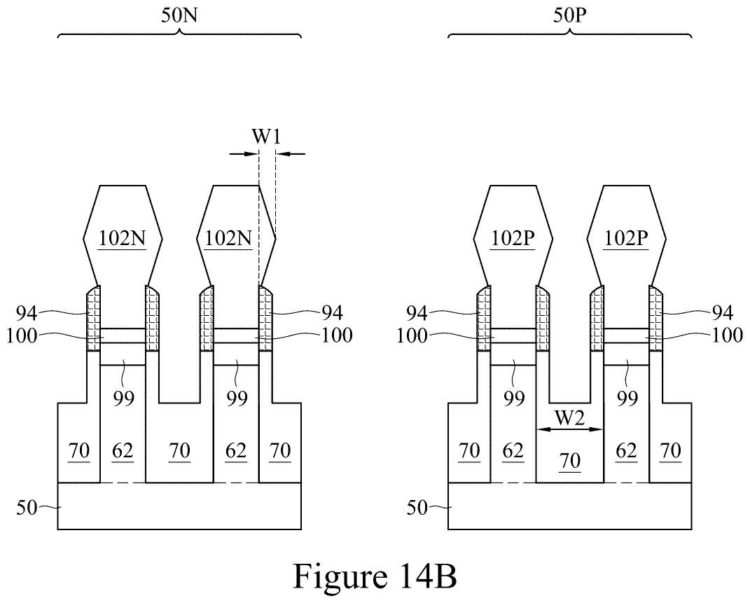

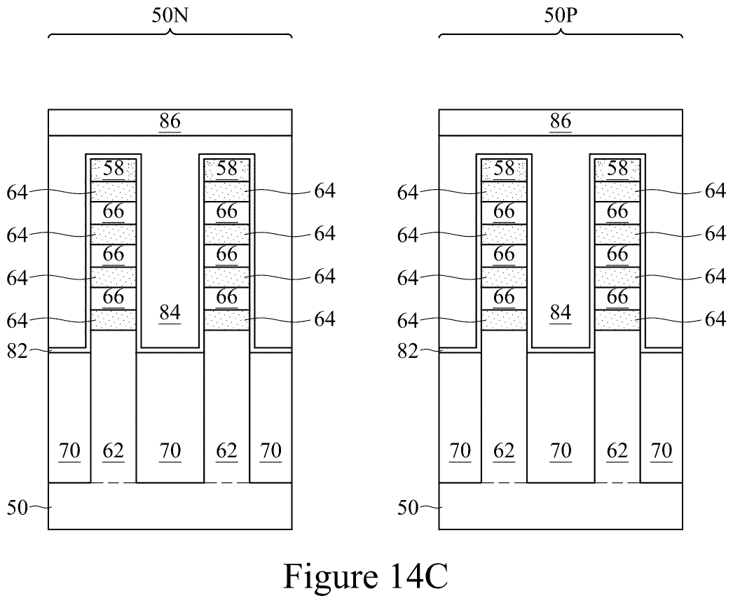

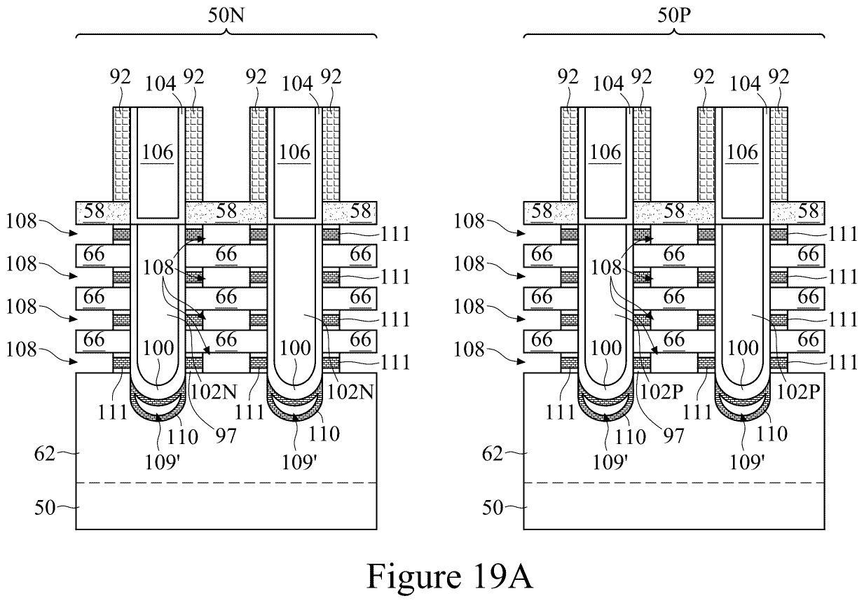

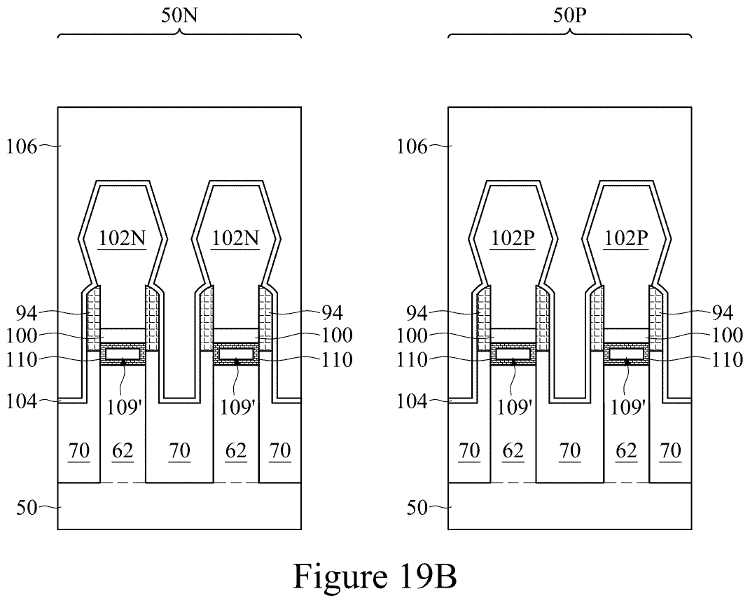

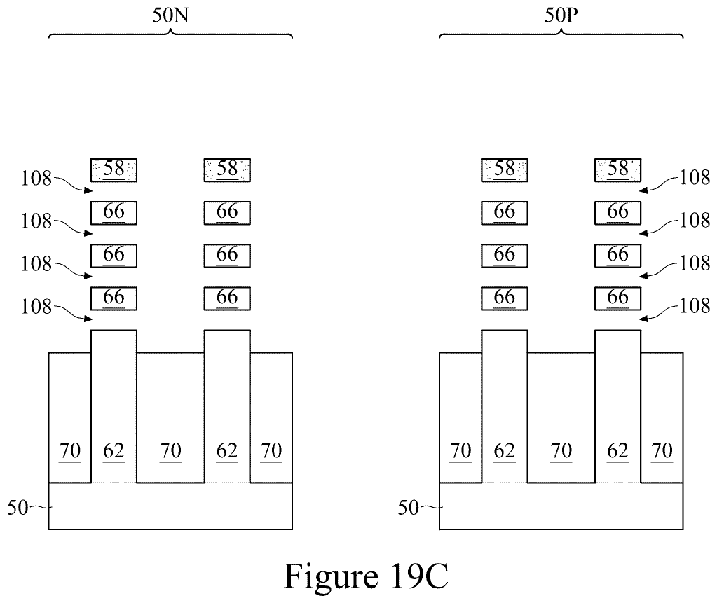

In FIGS. 14A-14C, epitaxial source/drain regions 102 are formed on the source/drain seed layers 100 in the source/drain recesses 96, in accordance with some embodiments. In some cases, forming epitaxial source/drain regions 102 on source/drain seed layers 100 (e.g., rather than on other layers) can allow for epitaxial source/drain regions 102 having improved quality, improved uniformity, and reduced defects. Additionally, forming epitaxial source/drain regions 102 before forming inner spacers 111 (see FIGS. 19A-C) can allow for epitaxial source/drain regions 102 having improved quality and uniformity. The epitaxial source/drain regions 102 include epitaxial source/drain regions 102N formed on the source/drain seed layers 100 in the n-type region 50N and epitaxial source/drain regions 102P formed on the source/drain seed layers 100 in the p-type region 50P. Accordingly, “epitaxial source/drain regions 102” may refer to the epitaxial source/drain regions 102N and/or the epitaxial source/drain regions 102P. The epitaxial source/drain regions 102N in the n-type region 50N may also be referred to as “n-type source/drain regions,” and the epitaxial source/drain regions 102P in the p-type region 50P may also be referred to as “p-type source/drain regions.” Portions of the second nanostructures 66 which act as the channel regions in subsequently completed nanostructure-FETs are disposed between neighboring pairs of the epitaxial source/drain regions 102N in the n-type region 50N or between neighboring pairs of the epitaxial source/drain regions 102P in the p-type region 50P.

In some embodiments, the p-type source/drain regions 102P are formed in the p-type region 50P before n-type source/drain regions 102N are formed in the n-type region 50N. For example, during formation of the p-type source/drain regions 102P, the n-type region 50N may be covered by a mask (not illustrated), which may be a hard mask, a photoresist mask, or the like. The mask is removed after formation of the p-type source/drain regions 102P using a suitable process, such as an etching process, an ashing process, or the like. In other embodiments, the n-type source/drain regions 102N in the n-type region 50N may be formed before the p-type source/drain regions 102P are formed in the p-type region 50P. In other embodiments, the epitaxial source/drain regions 102N and the epitaxial source/drain regions 102P may be formed simultaneously.

The epitaxial source/drain regions 102N may include any acceptable material appropriate for n-type nano-FETs. For example, epitaxial source/drain regions 102N may include materials exerting a tensile strain on the second nanostructures 66, such as silicon, silicon carbide, phosphorous doped silicon carbide, silicon phosphide, or the like. The epitaxial source/drain regions 102P may include any acceptable material appropriate for p-type nano-FETs. For example, epitaxial source/drain regions 102P may include materials exerting a compressive strain on the second nanostructures 66,, such as silicon-germanium, boron doped silicon-germanium, germanium, germanium tin, or the like. Other materials or combinations of materials are possible. The epitaxial source/drain regions 102N and/or epitaxial source/drain regions 102P may comprise one or more semiconductor material layers. In some embodiments, the epitaxial source/drain regions 102 may exert stress on adjacent second nanostructures 66, thereby improving performance. The epitaxial source/drain regions 102 may protrude higher than the first nanostructures 64 and may have facets.

The epitaxial source/drain regions 102N, the epitaxial source/drain regions 102P, the second nanostructures 66, and/or the substrate 50 may be implanted with dopants to form source/drain regions, similar to the process previously discussed for forming lightly-doped source/drain regions, followed by an anneal. The source/drain regions may have an impurity concentration of between about 1×10¹⁹ atoms/cm³ and about 1×10²¹ atoms/cm³. The n-type and/or p-type impurities for source/drain regions may be any of the impurities previously discussed. In some embodiments, the epitaxial source/drain regions 102N and/or the epitaxial source/drain regions 102P may be in situ doped during growth.

As a result of the epitaxy processes used to form the epitaxial source/drain regions 102, upper surfaces of the epitaxial source/drain regions 102 may have facets which protrude laterally outward beyond sidewalls of the fins 62. In the illustrated embodiments, the fin spacers 94 are formed on top surfaces of the STI regions 70, thereby blocking the epitaxial growth. In some other embodiments, the fin spacers 94 may cover portions of the sidewalls of the nanostructures 64/66 and/or the fins 62, further blocking the epitaxial growth. In another embodiment, the spacer etch used to form the gate spacers 92 is controlled to not form the fin spacers 94, so as to allow the epitaxial source/drain regions 102 to extend to the surface of the STI region 70. In some embodiments, the epitaxial source/drain regions 102 extend above a top surface of the first nanostructures 64 and/or the second nanostructures 66. As a result, a top surface of an epitaxial source/drain region 102 may be disposed further from the substrate 50 than a top surface of the first nanostructures 64 and/or the second nanostructures 66.

In some embodiments, adjacent epitaxial source/drain regions 102 remain separated after the epitaxy process is completed as illustrated by FIG. 14B. In some embodiments, growing the epitaxial source/drain regions 102 on seed layers 100 as described herein can allow for improved uniformity and control of the lateral growth of the epitaxial source/drain regions 102. For example, in some cases, the epitaxial source/drain regions 102 may be grown having a smaller lateral width, also resulting in a smaller volume. In some embodiments, the epitaxial source/drain regions 102 may have a laterally protruding width W1 that is less than about 20 nm, though other widths are possible. Forming epitaxial source/drain regions with a smaller lateral width or a smaller volume can reduce variation and allow for higher device density without increasing the risk of undesirably merging adjacent epitaxial source/drain regions 102. In some cases, forming epitaxial source/drain regions 102 having smaller volume or smaller width W1 can reduce parasitic capacitance, which can improve device speed and performance. In some cases, the uniformity (U %) of epitaxial source/drain regions 102 may be about 20% or less. In some cases, the improved uniformity and smaller lateral width of the epitaxial source/drain regions 102 described herein can allow for a smaller width W2 between adjacent fins 62, which can increase the density of nano-FETs. In some embodiments, the width W2 between fins 62 may be in the range of about 5 nm to about 50 nm, though other widths are possible.

In some cases, forming the epitaxial source/drain regions 102 on the source/drain seed layers 100 can form epitaxial source/drain regions 102 having fewer defects. Reducing the defects within the epitaxial source/drain regions 102 can result in larger strain applied to the channel regions of the second nanostructures 66, which can improve device performance. For example, the epitaxial source/drain regions 102P can exert increased compressive strain in the respective channel regions of the second nanostructures 66 within the p-type region 50P, thereby improving performance. In some cases, the epitaxial source/drain regions 102N can exert increased tensile strain in the respective channel regions of the second nanostructures 66 within the n-type region 50N, thereby improving performance. In some cases, the techniques described herein allow for the epitaxial source/drain regions 102 to exert stress on the second nanostructures 66 that is in the range of about 0 GPa to about 2 GPa, though other values are possible. In some cases, the improved strain due to techniques described herein can increase the current of a nano-FET as much as about 9%, though other values are possible. In this manner, by improving the quality of the epitaxial source/drain regions 102 using source/drain seed layers 100 as described herein, device performance, device uniformity, device density, and/or device yield can be improved.

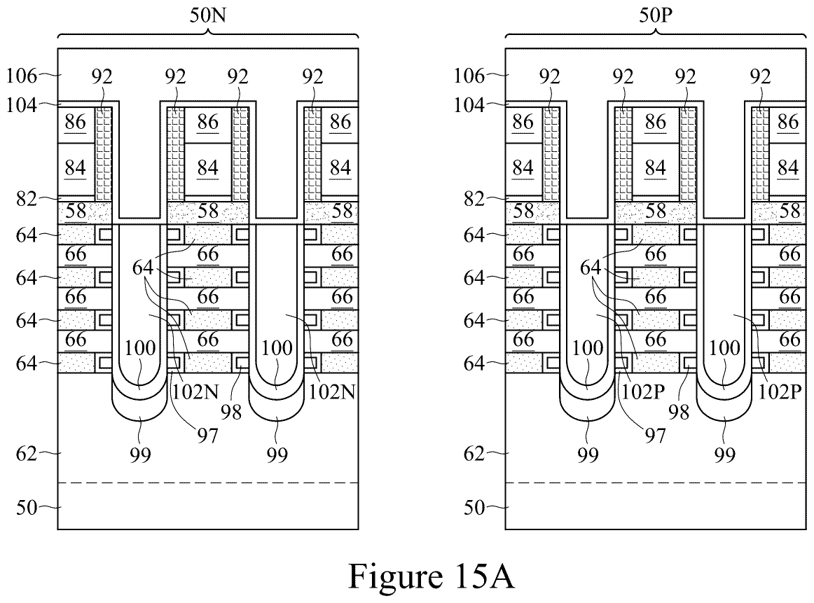

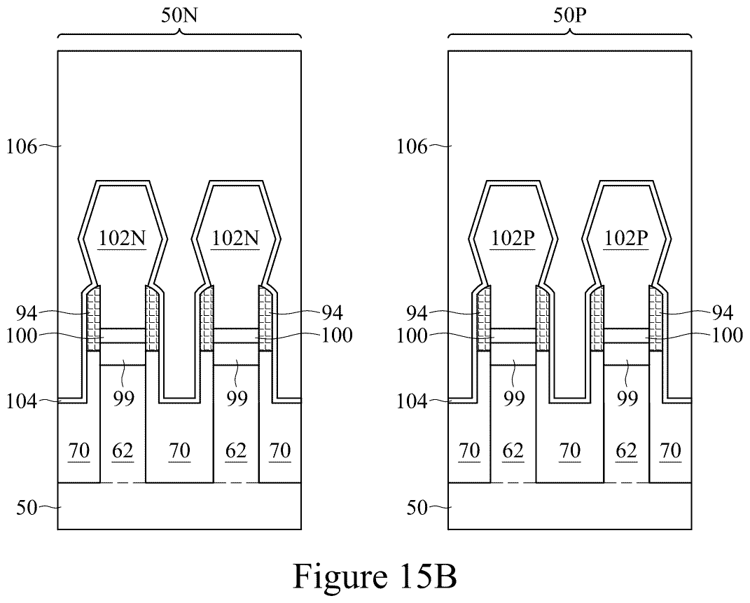

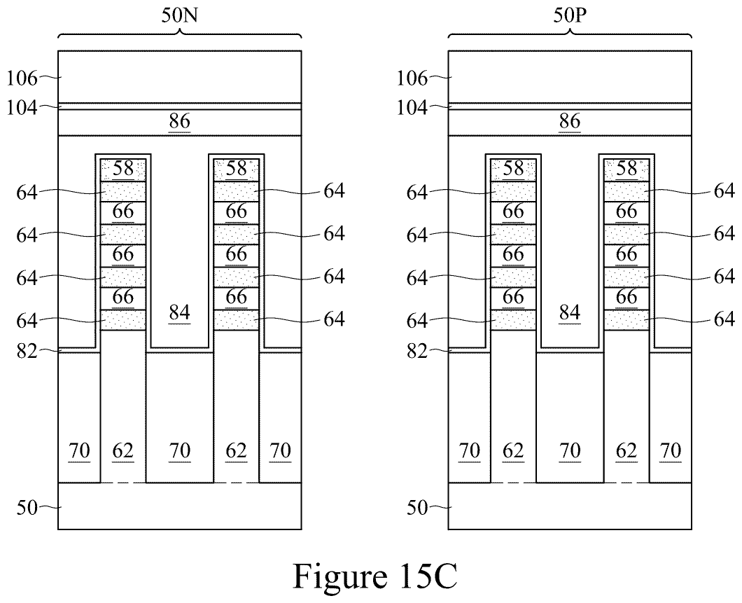

In FIGS. 15A-15C, a first inter-layer dielectric (ILD) 106 is deposited over the epitaxial source/drain regions 102, the fin spacers 94, the gate spacers 92, the hard mask 58, the masks 86 (if present), and/or the dummy gates 84. The first ILD 106 may be formed of a dielectric material, which may be deposited by any suitable method, such as CVD, plasma-enhanced CVD (PECVD), or FCVD. Suitable dielectric materials may include silicon oxide, phospho-silicate glass (PSG), boro-silicate glass (BSG), boron-doped phospho-silicate glass (BPSG), undoped silicate glass (USG), or the like. Other insulation materials formed by any acceptable process may be used.

In some embodiments, a contact etch stop layer (CESL) 104 is formed between the first ILD 106 and the epitaxial source/drain regions 102, the fin spacers 94, the gate spacers 92, the hard mask 58, the masks 86 (if present), and/or the dummy gates 84. The CESL 104 may be formed of a dielectric material having a high etching selectivity from the etching of the first ILD 106, such as silicon nitride, silicon oxide, silicon oxynitride, a combination thereof, or the like, which may be formed using any suitable deposition process, such as CVD, ALD, or the like.

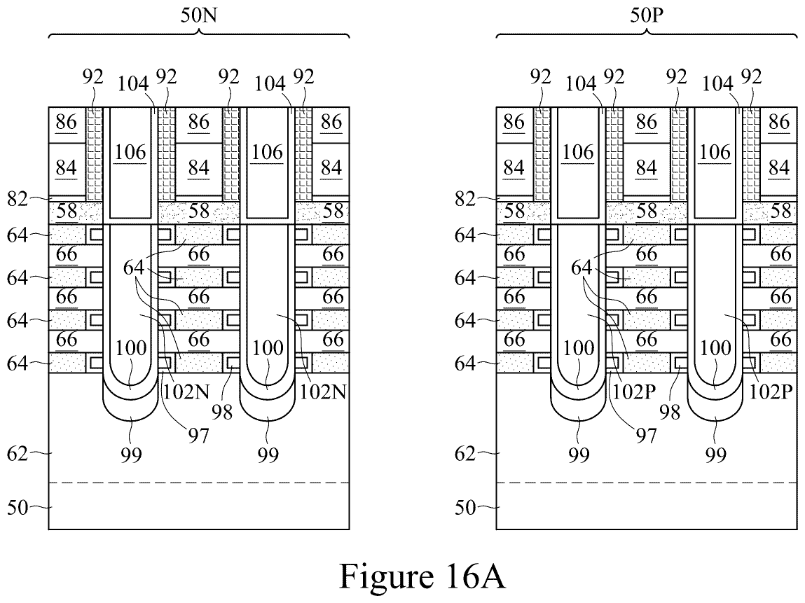

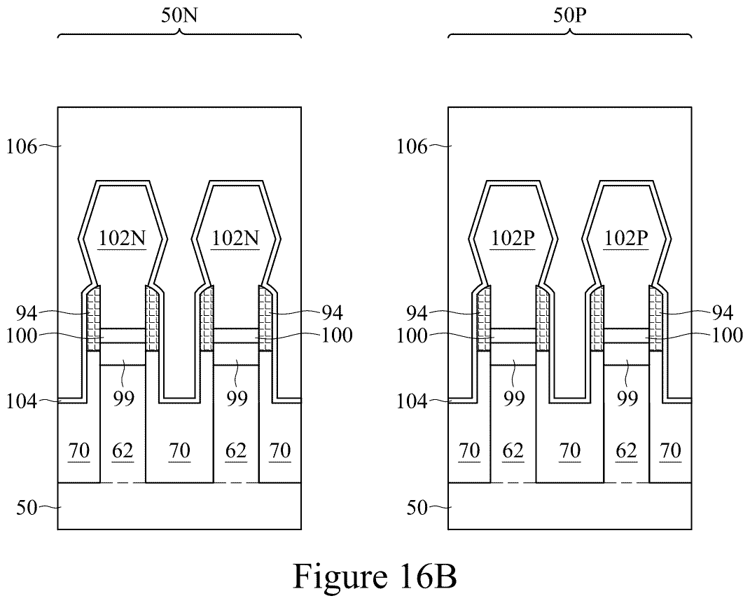

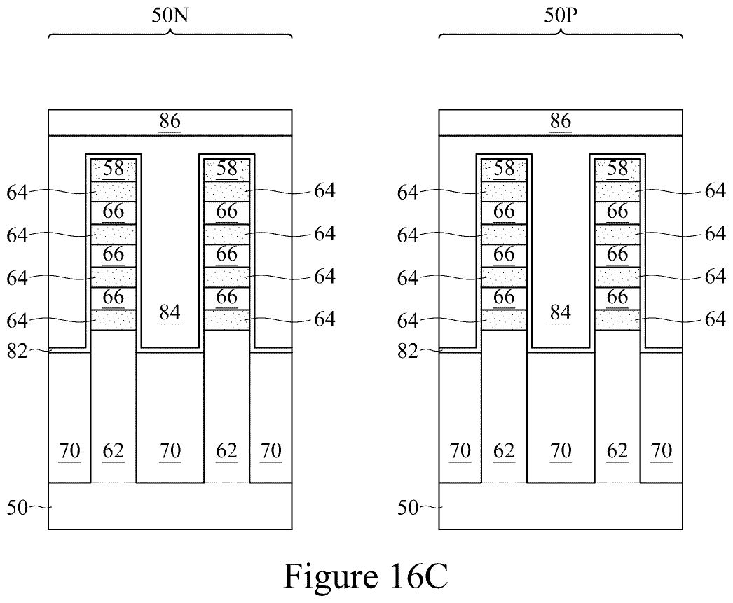

In FIGS. 16A-16C, a removal process is performed to level the top surfaces of the first ILD 106 with the top surfaces of the gate spacers 92 and the masks 86 (if present) or the dummy gates 84. In some embodiments, the removal process comprises a planarization process such as a chemical mechanical polish (CMP), a grinding process, an etch-back process, a combination thereof, or the like. The planarization process may also remove the masks 86 on the dummy gates 84, and portions of the gate spacers 92 along sidewalls of the masks 86. After the planarization process, top surfaces of the first ILD 106, the gate spacers 92, and the masks 86 (if present), and/or the dummy gates 84 are substantially level or coplanar (within process variations). Accordingly, the top surfaces of the masks 86 (if present) and/or the dummy gates 84 may be exposed through the first ILD 106.

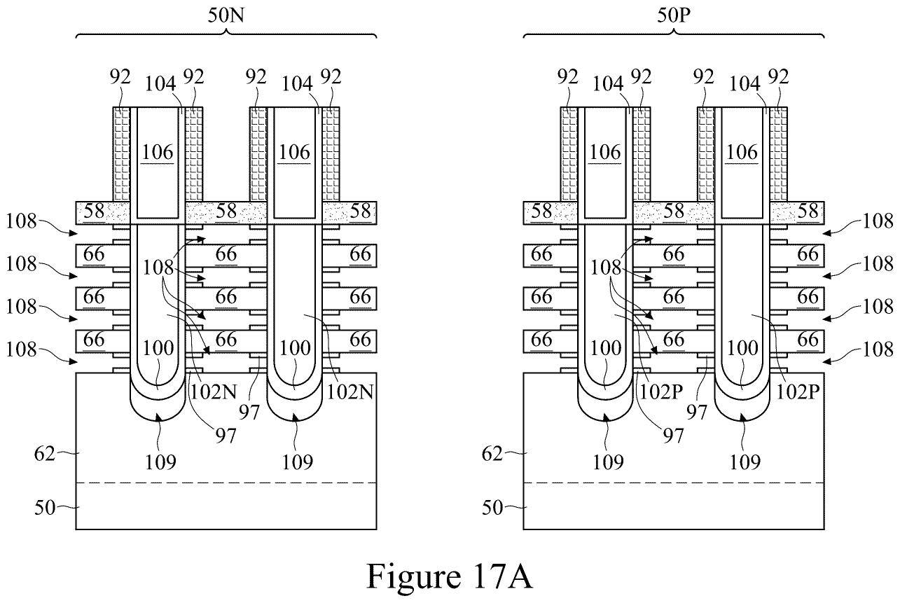

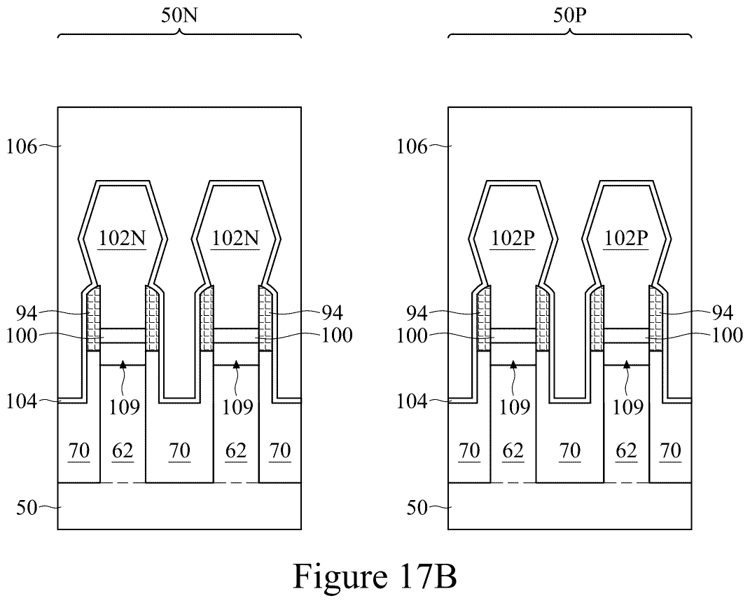

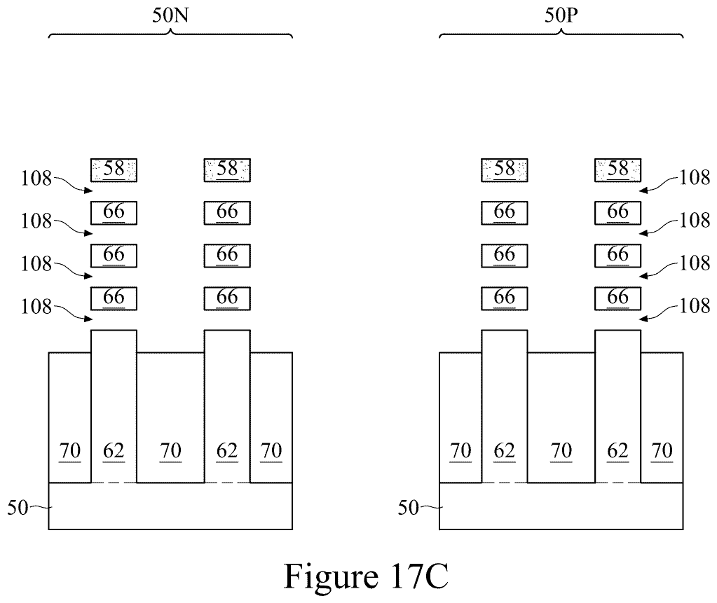

In FIGS. 17A-17C, the masks 86 (if present) and the dummy gates 84 are removed in one or more etching steps, such that recesses are formed between the gate spacers 92. Portions of the dummy dielectrics 82 are also removed. In some embodiments, the dummy gates 84 and the dummy dielectrics 82 are removed using an anisotropic dry etch process. For example, the etching process may include a dry etch process using reaction gas(es) that selectively etch the material of the dummy gates 84 at a faster rate than the materials of the first ILD 106 and the gate spacers 92. During the removal, the dummy dielectrics 82 and/or the hard mask 58 may be used as etch stop layers when the dummy gates 84 are etched. The dummy dielectrics 82 may then be removed after the removal of the dummy gates 84. Removing the dummy dielectrics 82 exposes top surfaces of the hard mask 58.

The remaining portions of the first nanostructures 64, the sacrificial spacers 98, and portions of the spacer liner 97 are then removed to form openings 108 in regions between the second nanostructures 66, in accordance with some embodiments. The sacrificial layers 99 are also removed to form openings 109 between the source/drain seed layers 100 and the fins 62, in accordance with some embodiments. The first nanostructures 64, the sacrificial spacers 98, the sacrificial layers 99, and the portions of the spacer liner 97 can be removed using any acceptable etch process that selectively etches the material(s) of the first nanostructures 64, the sacrificial spacers 98, and the sacrificial layers 99 at a faster rate than the material(s) of the second nanostructures 66 and the source/drain seed layers 100. The etching may be isotropic. For example, when the first nanostructures 64 are formed of silicon germanium and the second nanostructures 66 are formed of silicon, the etch process may be a wet etch using tetramethylammonium hydroxide (TMAH), ammonium hydroxide (NH₄OH), or the like.

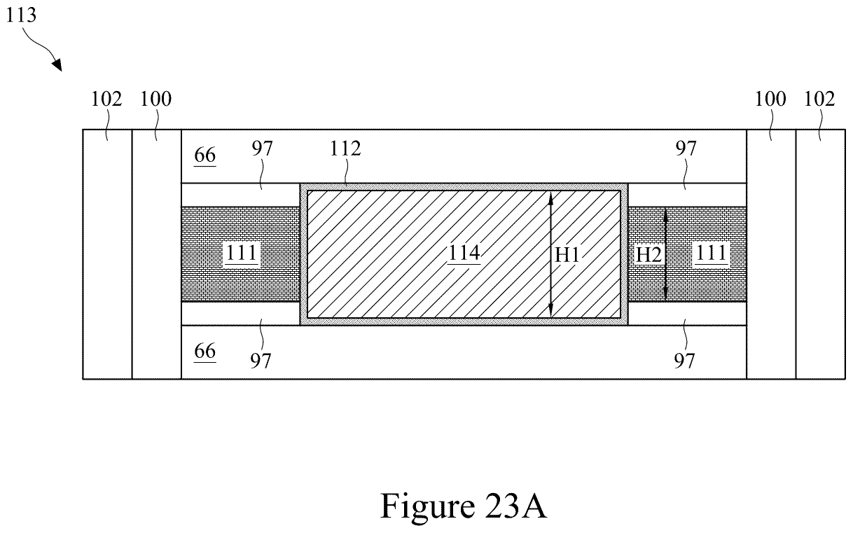

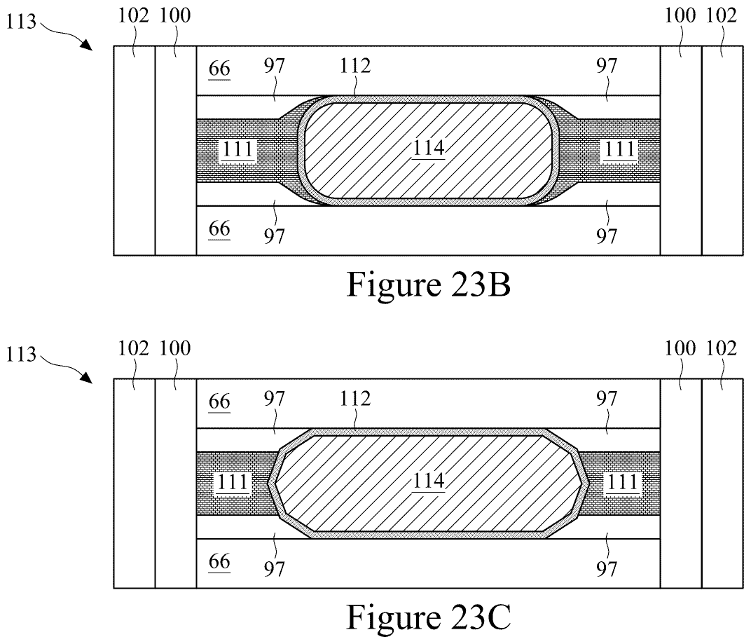

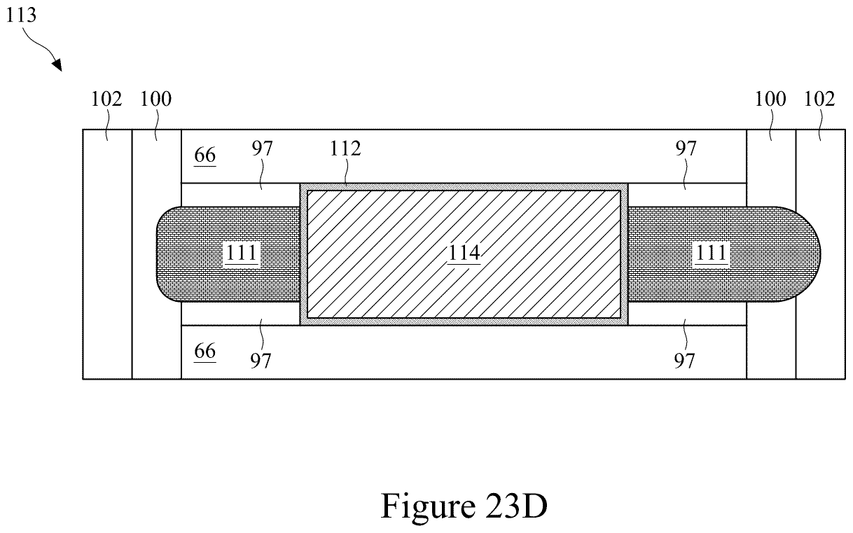

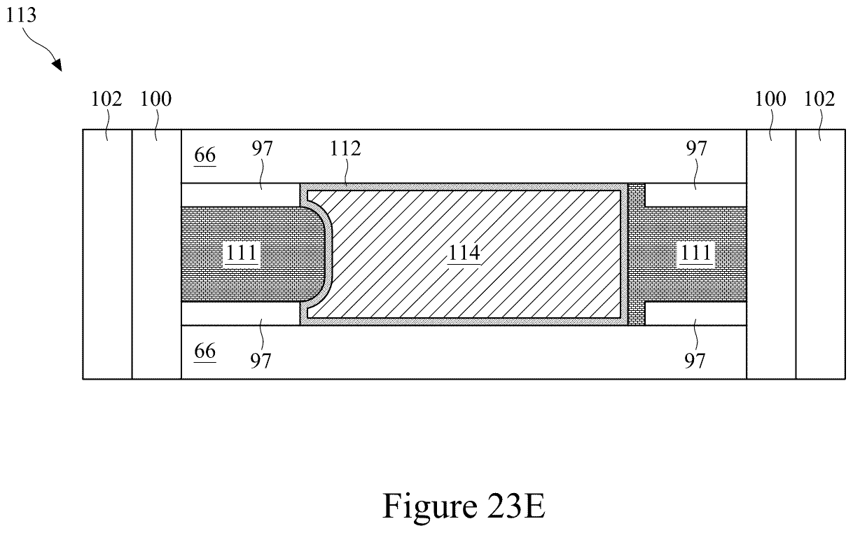

As shown in FIG. 17A, the etch process may remove portions of the spacer liner 97 covering the source/drain seed layers 100, exposing sidewall surfaces of the source/drain seed layers 100. The etch process may also etch the exposed sidewall surfaces of the source/drain seed layers 100, in some embodiments. Accordingly, the source/drain seed layers 100 may be recessed where the exposed surfaces source/drain seed layers 100 were etched by the etch process. In some cases, the recesses may extend through the source/drain seed layers 100 and into the epitaxial source/drain regions 102. An example of the etch process recessing source/drain seed layers 100 and/or the epitaxial source/drain region 102 is described below for FIG. 23D. After the etch process, portions of the spacer liner 97 may remain on top surfaces and/or bottom surfaces of the second nanostructure 66, in some cases. Portions of the spacer liner 97 may also remain on top surfaces of the fins 62 and bottom surfaces of the hard mask 58. Accordingly, central regions of the openings 108 may have a greater height than regions of the openings 108 near the epitaxial source/drain regions 102. The etch process may remove the sacrificial layers 99, leaving openings 109 (e.g., air gaps) underneath the source/drain seed layers 100. In some embodiments, a trim process (not separately illustrated) is performed to decrease the thicknesses of the exposed portions of the second nanostructures 66 and expand the openings 108. The trim process may remove or thin portions of the spacer liner 97, in some cases. Hereinafter, the second nanostructures 66 may be referred to as nanostructures 66, and the nanostructures 66 over each fin 62 may be referred to as “stacks” of nanostructures 66.

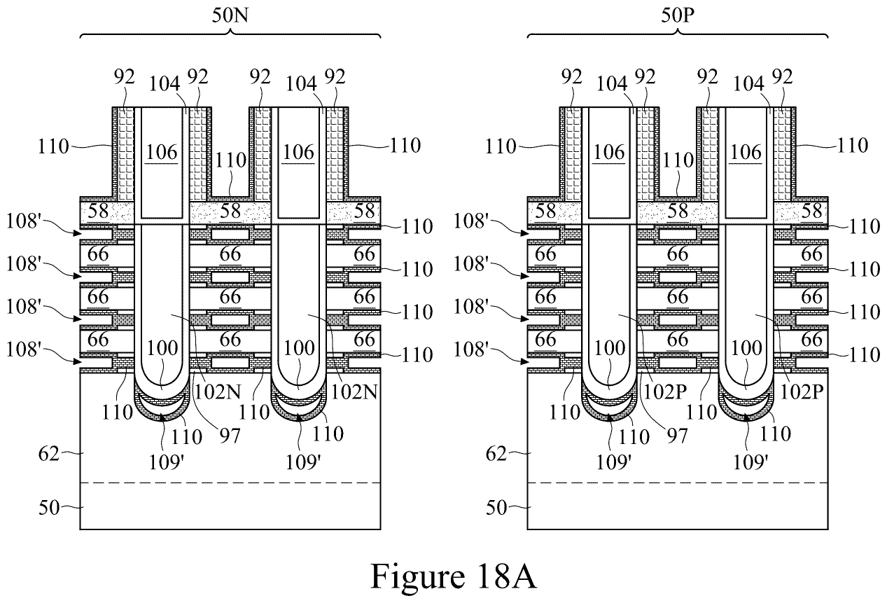

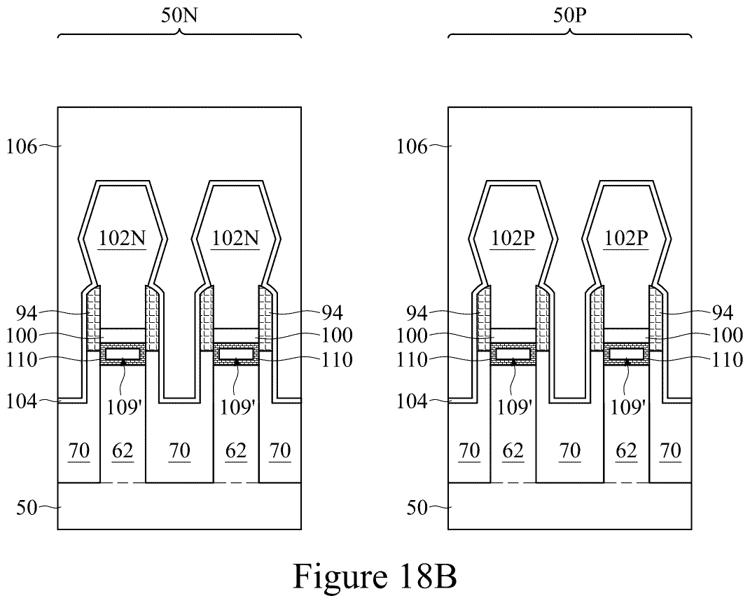

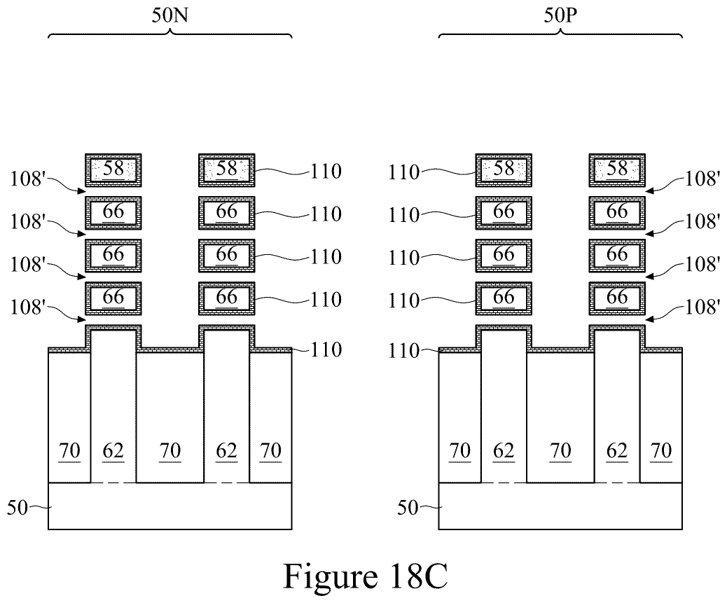

In FIGS. 18A-18C, spacer material 110 is conformally deposited in the openings 108 and in the openings 109, in accordance with some embodiments. The spacer material 110 may also be conformally deposited on surfaces of the first ILD 70, the fins 62, the hard mask 58, and the gate spacers 92. As shown in FIG. 18C, the spacer material 110 may fully surround (e.g., “wrap around”) portions of the hard mask 58 and the nanostructures 66, in some cases. The spacer material 110 may also be conformally deposited on surfaces of the source/drain seed layers 100 and fins 62 in the openings 109. In some embodiments, the spacer material 110 does not completely fill the openings 108 or the openings 109, leaving remaining openings 108′ and openings 109′. The remaining openings 108′ or 109′ may be voids or air gaps, in some cases. For example, in some cases, the spacer material 110 deposited on the fins 62 in the opening 109 may merge with the spacer material 110 deposited on the source/drain seed layers 100 in the openings 109 such that the openings 109′ are sealed by the spacer material 110. In other embodiments, the spacer material 110 completely fills the openings 108 or the openings 109. An example in which the spacer material 110 completely fills the opening 109 is described below for FIG. 24. Seams may be present in merged regions of the spacer material 110, in some cases. The spacer material 110 in the openings 109 is underneath the source/drain seed layers 100 and separates the source/drain seed layers 100 from the fin 62 and the substrate 50. Accordingly, the spacer material 110 in the openings 109 may be considered an insulating layer or an isolation structure in some cases.

In some embodiments, the spacer material 110 may be an insulating material such as silicon oxide, germanium oxide, silicon oxycarbide, silicon nitride, silicon oxynitride, silicon oxycarbonitride, silicon carbonitride, the like, or a combination thereof. However, the spacer material 110 may be suitable material(s), such as materials having a dielectric constant (e.g., k-value) less than about 8 or other materials such as semiconductor materials or the like. The spacer material 110 may be formed using a suitable deposition process, such as ALD, CVD, or the like. The spacer material 110 may be conformally deposited to a thickness in the range of about 1 nm to about 15 nm, though other thicknesses are possible.

In FIGS. 19A-19C, an etch process is performed to remove portions of the spacer material 110 and form inner spacers 111, in accordance with some embodiments. As will be subsequently described in greater detail, gate structures are subsequently formed in the openings 108 between inner spacers 111. The inner spacers 111 act as isolation features between the epitaxial source/drain regions 102 and the subsequently formed gate structures. In some cases, forming the inner spacers 111 after forming the epitaxial source/drain regions 102 can allow the epitaxial source/drain regions 102 to be formed having better quality and fewer defects.

The etch process removes middle portions of the spacer material 110, with the remaining portions of the spacer material 110 forming the inner spacers 111. The remaining portions of the spacer material 110 (e.g., the inner spacers 111) may be on sidewalls of the source/drain seed layers 100 and may be sandwiched between regions of spacer liner 97. The etch process can remove spacer material 110 from surfaces of the gate spacers 92, the nanostructures 66, and the hard mask 58. Accordingly, after performing the etch process, openings 108 are located laterally between inner spacers 111 and vertically between nanostructures 66. An opening 108 may have a height that is greater than a height of an adjacent inner spacer 111, in some cases. The etching of the spacer material 110 may be isotropic or anisotropic. For example, the etch process may include an isotropic dry etch and/or an anisotropic dry etch such as a RIE, a NBE, or the like. In some embodiments, the etch process comprises a wet etch. While the process described for FIGS. 18A-18C and 19A-19C forms inner spacers 111 using a single deposition process followed by a single etch process, in other embodiments inner spacers 111 may be formed using multiple cycles of deposition and etching.

Although outer sidewalls of inner spacers 111 are illustrated as being flush (e.g. approximately coplanar) with sidewalls of the spacer liner 97, the outer sidewalls of the inner spacers 111 may extend beyond or be recessed from sidewalls of the spacer liner 97. In other words, the inner spacers 111 may partially fill, completely fill, or overfill the regions above or below the spacer liner 97. Inner spacers 111 recessed from sidewalls of the spacer liner 97 may be formed, for example, by etching the spacer material 110 for a relatively longer amount of time to remove more of the spacer material 110. Inner spacers 111 protruding from sidewalls of the spacer liner 97 may be formed, for example, by etching the spacer material 110 for a relatively shorter amount of time to leave more remaining spacer material 110. Some non-limiting examples of possible inner spacers 111 are described below for FIGS. 23A-23E. Moreover, although the sidewalls of the inner spacers 111 are illustrated as being flat, the sidewalls of the inner spacers 111 may be concave or convex. The profile of the sidewalls of the inner spacers 111 may be controlled by controlling the parameters or techniques used for the etch process, in some embodiments. In some cases, the inner spacers 111 may cover sidewalls of the spacer liner 97. In some embodiments, an inner spacer 111 may have a width in the range of about 1 nm to about 15 or may have a height in the range of about 1 nm to about 15 nm. Other dimensions are possible.

In some embodiments, the spacer material 110 between the fins 62 and the source/drain seed layers 100 (e.g., within the opening 109) is not fully removed, and portions of the spacer material 110 may remain on surfaces of the fins 62 and/or the source/drain seed layers 100. In some embodiments, the openings 109′ remain sealed by the spacer material 110. In some cases, forming openings 109′ between the fins 62 and the source/drain seed layers 100 can reduce parasitic capacitance and improve device performance.

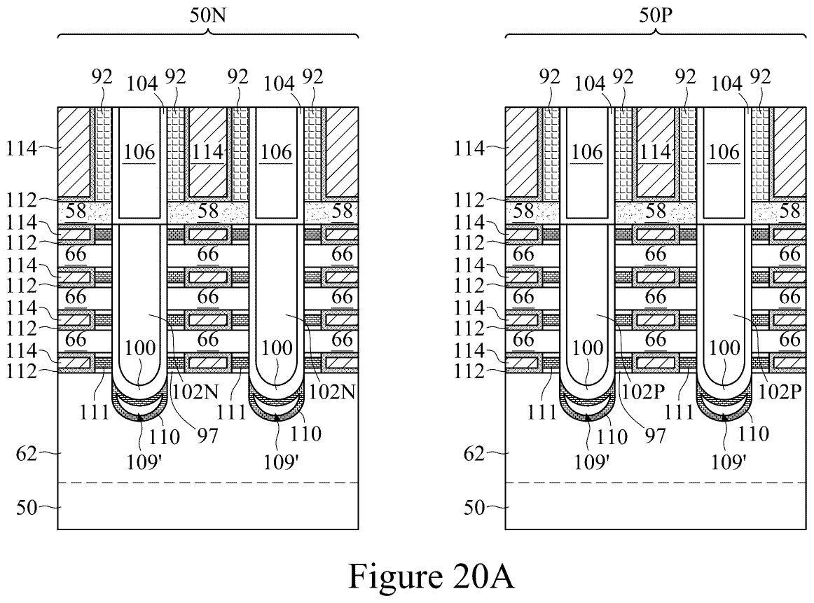

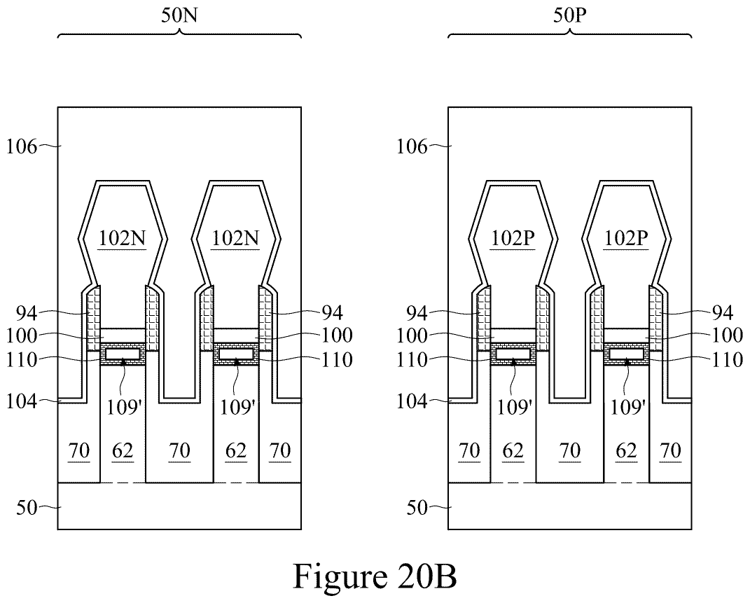

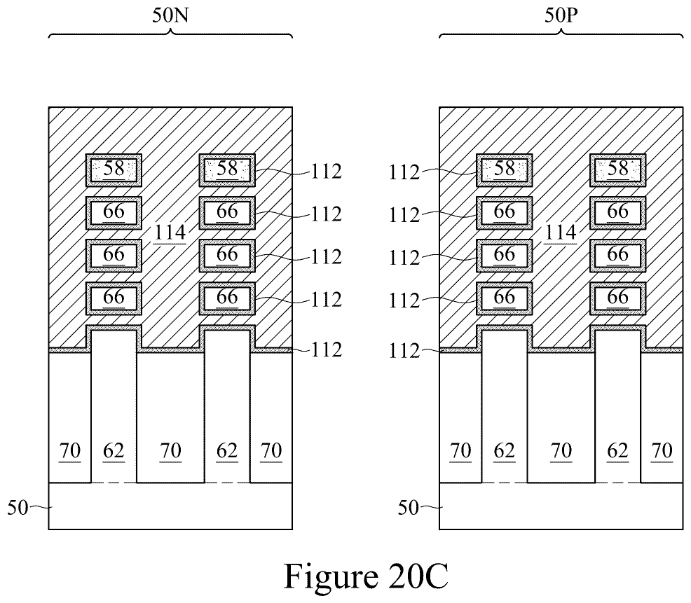

In FIGS. 20A-20C, gate dielectrics 112 and gate electrodes 114 are formed for replacement gates, in accordance with some embodiments. Each respective pair of a gate dielectric 112 and a gate electrode 114 may be collectively referred to as a “gate structure” or a “gate stack.” Each gate structure is wrapped around a channel region of a nanostructure 66, such that the gate structure extends along sidewalls, a bottom surface, and a top surface of the nanostructure 66. Some of the gate structures also wrap around the hard mask 58 or also extend along sidewalls and/or a top surface of a fin 62.

The gate dielectrics 112 include one or more gate dielectric layer(s) disposed on the sidewalls and/or the top surfaces of the fins 62; on the top surfaces, the sidewalls, and the bottom surfaces of the channel regions of the nanostructures 66; on the top surfaces, the sidewalls, and the bottom surfaces of the hard mask 58; on the sidewalls of the inner spacers 111; and on the sidewalls of the gate spacers 92. The gate dielectrics 112 may be formed of an oxide such as silicon oxide or a metal oxide, a silicate such as a metal silicate, combinations thereof, multi-layers thereof, or the like. Additionally or alternatively, the gate dielectrics 112 may be formed of a high-k dielectric material (e.g., dielectric materials having a k-value greater than about 7.0), such as a metal oxide or a silicate of hafnium, aluminum, zirconium, lanthanum, manganese, barium, titanium, lead, and combinations thereof. The dielectric material(s) of the gate dielectrics 112 may be formed by molecular-beam deposition (MBD), ALD, PECVD, or the like. Although single-layered gate dielectrics 112 are illustrated, the gate dielectrics 112 may include any number of interfacial layers and any number of main layers. For example, the gate dielectrics 112 may include an interfacial layer and an overlying high-k dielectric layer.

The gate electrodes 114 include one or more gate electrode layer(s) disposed over the gate dielectrics 112. The gate electrodes 114 may be formed of a metal-containing material such as titanium nitride, titanium oxide, tantalum nitride, tantalum carbide, tungsten, cobalt, ruthenium, aluminum, combinations thereof, multi-layers thereof, or the like. Although single-layered gate electrodes 114 are illustrated, the gate electrodes 114 may include any number of work function tuning layers, any number of barrier layers, any number of glue layers, and a fill material.

As an example to form the gate structures, one or more gate dielectric layer(s) may be deposited in the openings 108. The gate dielectric layer(s) may also be deposited on the top surfaces of the first ILD 106, the CESL 104, and the gate spacers 92. Subsequently, one or more gate electrode layer(s) may be deposited on the gate dielectric layer(s), and in the remaining portions of the openings 108. A removal process may then be performed to remove the excess portions of the gate dielectric layer(s) and the gate electrode layer(s), which excess portions are over the top surfaces of the first ILD 106, the CESL 104, and the gate spacers 92. In some embodiments, a planarization process such as a chemical mechanical polish (CMP), an etch-back process, a combination thereof, or the like may be utilized. The gate dielectric layer(s), after the removal process, have portions left in the openings 108 (thus forming the gate dielectrics 112). The gate electrode layer(s), after the removal process, have portions left in the openings 108 (thus forming the gate electrodes 114). When a planarization process is utilized, the top surfaces of the gate spacers 92, the CESL 104, the first ILD 106, the gate dielectrics 112, and the gate electrodes 114 are level or coplanar (within process variations). In embodiments in which the opening 109′ is sealed by the spacer material 110, the materials of the gate structures are not deposited within the opening 109′.

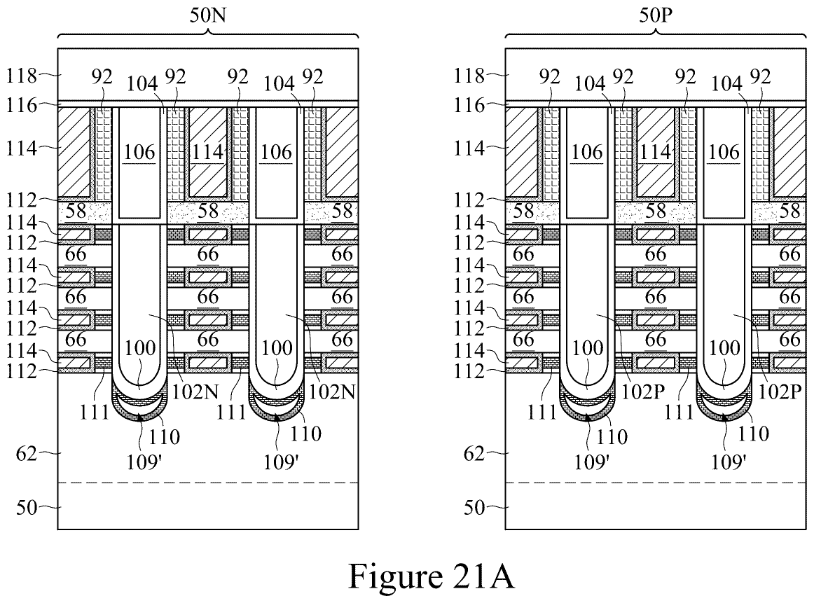

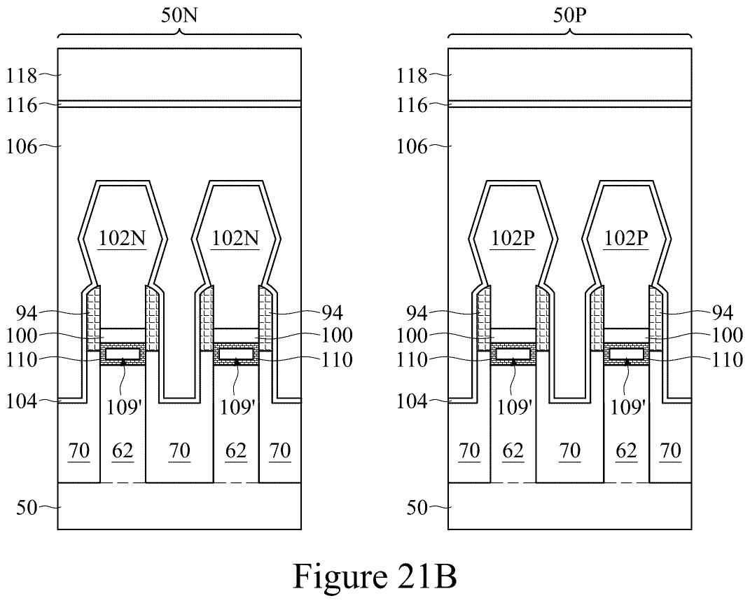

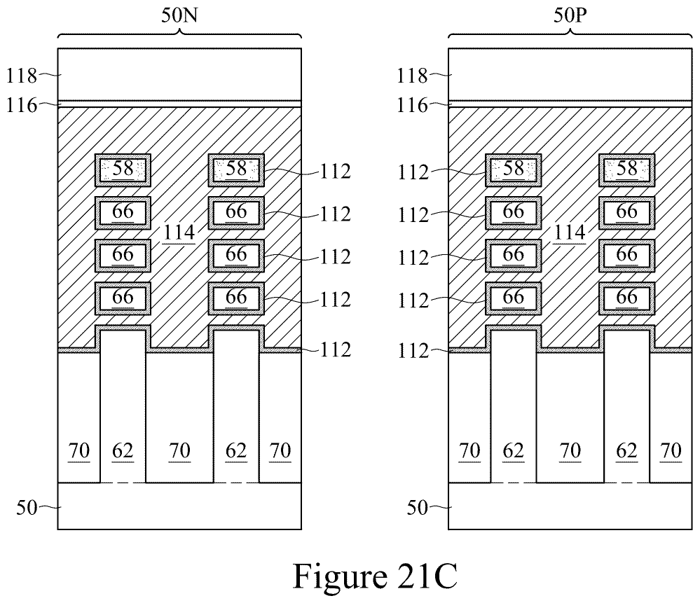

In FIGS. 21A-21C, a second ILD 118 is deposited over the gate spacers 92, the CESL 104, the first ILD 106, the gate dielectrics 112, and the gate electrodes 114. In some embodiments, the second ILD 118 is a flowable film formed by a flowable CVD method. In some embodiments, the second ILD 118 is formed of a dielectric material such as PSG, BSG, BPSG, USG, or the like, which may be formed by any suitable deposition process, such as CVD, PECVD, or the like.

In some embodiments, an etch stop layer (ESL) 116 is formed between the second ILD 118 and the gate spacers 92, the CESL 104, the first ILD 106, the gate dielectrics 112, and the gate electrodes 114. The ESL 116 may be formed of a dielectric material having a high etching selectivity from the etching of the second ILD 118, such as silicon nitride, silicon oxide, silicon oxynitride, or the like, which may be formed by any suitable deposition process, such as CVD, ALD, or the like.

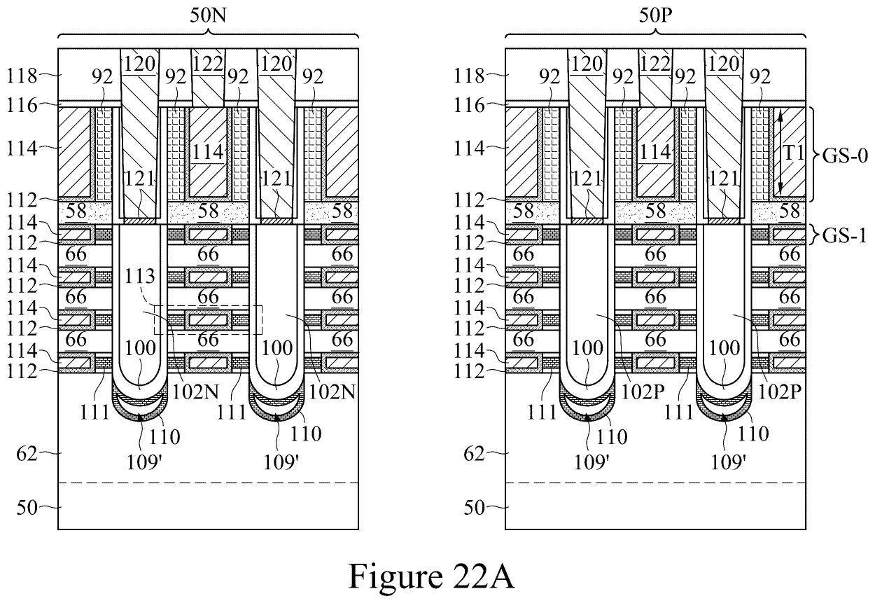

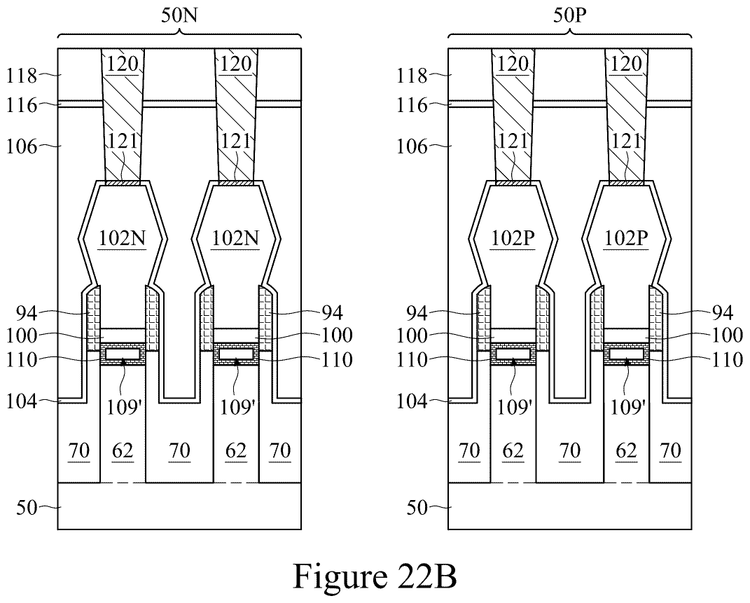

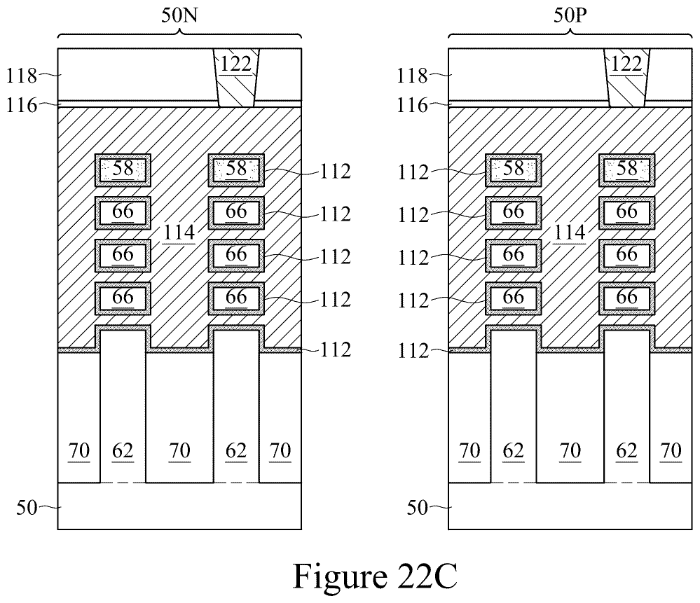

In FIGS. 22A-22C, gate contacts 122 and source/drain contacts 120 are formed to contact, respectively, the gate electrodes 114 and the epitaxial source/drain regions 102. The gate contacts 122 may be physically and electrically coupled to the gate electrodes 114. The source/drain contacts 120 may be physically and electrically coupled to the source/drain regions 102. In this manner, nano-FETs may be formed in the n-type region 50N and the p-type region 50P, in accordance with some embodiments. In some embodiments, the channel regions of the top-most nanostructures 66 are controlled by portions of the gate structure under the hard mask 58 that are on top surfaces of the top-most nanostructures 66 (e.g., the portions labeled “GS-1” in FIG. 22A). In such embodiments, the portions of the gate structure over top surfaces of the hard mask 58 (e.g., the portions labeled “GS-0” in FIG. 22A) do not control the channel regions of the top-most nanostructures 66. Accordingly, the portions GS-0 of the gate structure over top surfaces of the hard mask 58 may be formed having a smaller thickness, which can reduce parasitic capacitance and improve device performance. In some embodiments, the thickness T1 of the portions GS-0 of the gate structure over the hard mask 58 may be in the range of about 3 nm to about 15 nm, though other thicknesses are possible. In some embodiments, top surfaces of the epitaxial source/drain regions 102 may be approximately level with or higher than (e.g., protrude above) bottom surfaces of the portions GS-0 of the gate structure over the hard mask 58. In other words, top surfaces of the epitaxial source/drain regions 102 may be approximately level with or higher than top surfaces of the top-most nanostructures 66.

As an example to form the gate contacts 122 and the source/drain contacts 120, openings for the gate contacts 122 are formed through the second ILD 118 and the ESL 116, and openings for the source/drain contacts 120 are formed through the second ILD 118, the ESL 116, the first ILD 106, and the CESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be copper, a copper alloy, silver, gold, tungsten, cobalt, aluminum, nickel, or the like. A planarization process, such as a CMP, may be performed to remove excess material from a surface of the second ILD 118. The remaining liner and conductive material form the gate contacts 122 and the source/drain contacts 120 in the openings. The gate contacts 122 and the source/drain contacts 120 may be formed in distinct processes, or may be formed in the same process. Although shown as being formed in the same cross-sections, it should be appreciated that each of the gate contacts 122 and the source/drain contacts 120 may be formed in different cross-sections, which may avoid shorting of the contacts.

Optionally, metal-semiconductor alloy regions 121 are formed at the interfaces between the epitaxial source/drain regions 102 and the source/drain contacts 120. The metal-semiconductor alloy regions 121 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon germanide regions formed of both a metal silicide and a metal germanide, or the like. The metal-semiconductor alloy regions 121 can be formed before the material(s) of the source/drain contacts 120 by depositing a metal in the openings for the source/drain contacts 120 and then performing a thermal annealing process. The metal can be any metal capable of reacting with the semiconductor materials (e.g., silicon, silicon carbide, silicon germanium, germanium, etc.) of the epitaxial source/drain regions 102 to form a low-resistance metal-semiconductor alloy, such as nickel, cobalt, titanium, tantalum, platinum, tungsten, other noble metals, other refractory metals, rare earth metals, or their alloys. The metal may be formed by a deposition process such as ALD, CVD, PVD, or the like. After the thermal annealing process, a cleaning process, such as a wet clean, may be performed to remove any residual metal from the openings for the source/drain contacts 120, such as from surfaces of the metal-semiconductor alloy regions 121. The material(s) of the source/drain contacts 120 can then be formed on the metal-semiconductor alloy regions 121.

FIGS. 23A, 23B, 23C, 23D, and 23E illustrate magnified views of a nano-FET, in accordance with some embodiments. The magnified view shown in FIGS. 23A-23E may correspond approximately to the region 113 of the n-type region 50N shown in FIG. 22A, though FIGS. 23A-23E may represent a different region of a nano-FET or a region in the p-type region 50P. FIGS. 23A-23E illustrate non-limiting examples of different shapes or configurations that the inner spacers 111, the gate structures, and/or the surrounding regions may have, in accordance with some embodiments. Other shapes or configurations are possible, and the embodiments shown in FIGS. 23A-23E or variations thereof may be combined in other embodiments. In some cases, the shapes or configurations of the gate structures, inner spacers 111, spacer liner 97, source/drain seed layers 100, and/or epitaxial source/drain regions 102 may be controlled by controlling the various associated etch processes used during manufacture of the nano-FET.

FIG. 23A illustrates a gate structure having a rectangular shape, in accordance with some embodiments. In the embodiment of FIG. 23A, the inner spacers 111 have approximately flat sidewalls that are approximately flush with sidewalls of the spacer liner 97. In other embodiments, the sidewalls of the inner spacers 111 may have a different profile or may be laterally offset from the sidewalls of the spacer liner 97. As shown in FIG. 23A, due to the presence of the spacer liner 97, the inner spacers 111 have a height H2 that is less than a height H1 of the gate electrode 114. In some embodiments, the height H1 of the gate electrode 114 may be between about 2 nm and about 8 nm larger than the height H2 of the inner spacers 111, though other heights are possible. In some embodiments, the inner spacers 111 may have a width in the range of about 1 nm to about 15 nm, or a height H2 in the range of about 1 nm to about 15 nm. In some cases, these dimensions and relative heights may also apply to other shapes or configurations, including those shown in FIGS. 23B and 23C. Other dimensions are possible.

FIG. 23B illustrates a gate structure having a rounded shape, in accordance with some embodiments. In the embodiment of FIG. 23B, the inner spacers 111 have concave sidewalls, and the spacer liner 97 has curved or sloped sidewalls. The inner spacers 111 protrude beyond the spacer liner 97 and extend between the spacer liner 97 and the gate structure. In other embodiments, the inner spacers 111 may not extend between the spacer liner 97 and the gate structure. FIG. 23C illustrates a gate structure having an angled shape, in accordance with some embodiments. In the embodiment of FIG. 23C, the inner spacers 111 have concave angled sidewalls, and the spacer liner 97 has angled sidewalls. In the embodiment of FIG. 23C, the spacer liner 97 protrude beyond the inner spacers 111 and also contact the gate structure. These are examples, and other shapes, arrangements, profiles, or configurations are possible.

FIG. 23D shows an embodiment similar to that of FIG. 23A, except that the etch process used to remove portions of the spacer liner 97 (see FIGS. 17A-17C) has recessed portions of the source/drain seed layers 100 and/or the epitaxial source/drain regions 102. The left side of FIG. 23D illustrates a case in which the etch process partially recessed a source/drain seed layer 100, and the right side of FIG. 23D illustrates a case in which the etch process etched through the source/drain seed layer 100 and partially recessed an epitaxial source/drain region 100. As shown in FIG. 23D, the recessing by the etch process can form concave or curved sidewall regions of the source/drain seed layers 100 and/or the epitaxial source/drain regions 102. Accordingly, the subsequent deposition of the spacer material 110 can fill the recesses, forming inner spacers 111 that have convex surfaces corresponding to the concave surfaces of the recesses. The inner spacers 111 may protrude into the source/drain seed layers 100 and/or the epitaxial source/drain regions 102, in some embodiments. In some embodiments, an inner spacer 111 may protrude partially into the source/drain seed layers 100. In some embodiments, an inner spacer 111 may protrude fully through the source/drain seed layer 100 and into an epitaxial source/drain region 102. The inner spacers 111 on opposite sides of a gate structure portion may protrude different distances, in some cases. The recessed portions of the source/drain seed layer 100 and epitaxial source/drain region 102 of FIG. 23D are illustrative examples, and the recesses and/or inner spacers 111 may have other dimensions or shapes in other cases.

FIG. 23E shows an embodiment similar to that of FIG. 23A, except that the inner spacers 111 extend beyond sidewalls of the adjacent spacer liner 97. The left side of FIG. 23E illustrates a case in which the inner spacer 111 protrudes from the spacer liner 97 and into the gate structure. The right side of FIG. 23E illustrates a case in which the spacer material 110 of the inner spacer 111 covers sidewalls of the spacer liner 97 such that the inner spacer 111 extends between the gate structure and the spacer liner 97. The inner spacers 111 shown in FIG. 23E may be formed, for example, by controlling the etching of the spacer material 110 (see FIGS. 19A-19C).

FIG. 24 shows an embodiment similar to that of FIG. 22A, except the opening 109 (see FIG. 17A) is completely filled with the spacer material 110. For example, the spacer material 110 deposited on the source/drain seed layers 100 may fully merge with the spacer material 110 deposited on the fins 62. Thus, no opening 109′ is present between the source/drain seed layers 100 and the fins 62. In some cases, a seam may be present in the spacer material 110, though in other cases a seam may not be present. Filling in the opening 109 with spacer material 110 can reduce leakage and reduce parasitic capacitance, in some cases.

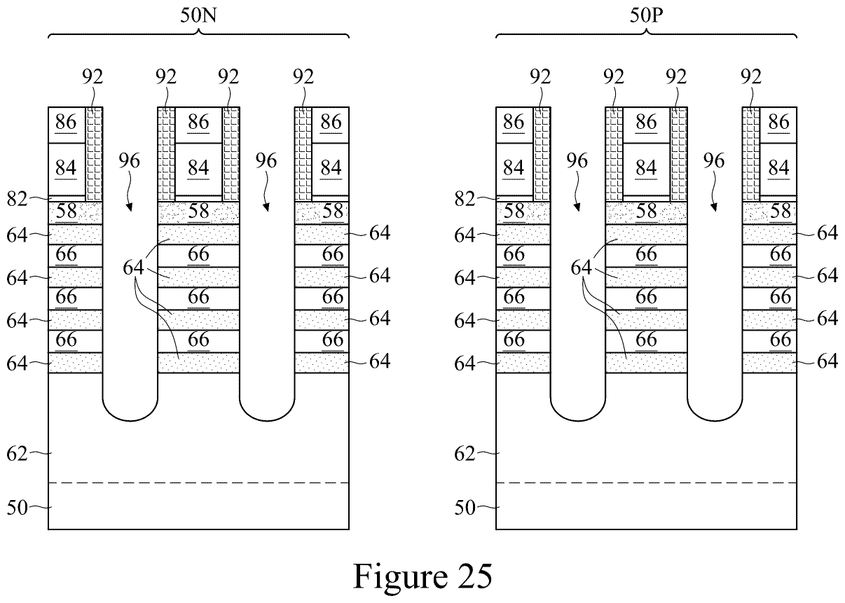

FIGS. 25 through 32 illustrate intermediate steps in the formation of nano-FETs, in accordance with some embodiments. The process steps of FIGS. 25-32 may be similar to the process steps shown in FIGS. 1-22C, except that spacer liner 97 and sacrificial spacers 98 are not formed, and the inner spacers 111 are formed using multiple deposition and etching cycles. Many of the materials or processes for FIGS. 25-32 may be similar to those described previously for FIGS. 1-22C, and some details may not be repeated. Additionally, FIGS. 25-32 illustrate cross-sectional views along a similar cross-section as reference cross-section A-A′ in FIG. 1.

FIG. 25 illustrates a structure similar to that shown previously in FIG. 9A, in accordance with some embodiments. For example, the structure of FIG. 25 illustrates source/drain recesses 96 formed in a stack of first nanostructures 64 and second nanostructures 66 over fins 62. A hard mask 58 may also be formed over the nanostructures 64/66, in some embodiments. The structure of FIG. 25 may be formed using similar processes and materials as described for forming the structure of FIG. 9A, such as those described for FIGS. 1-8C.

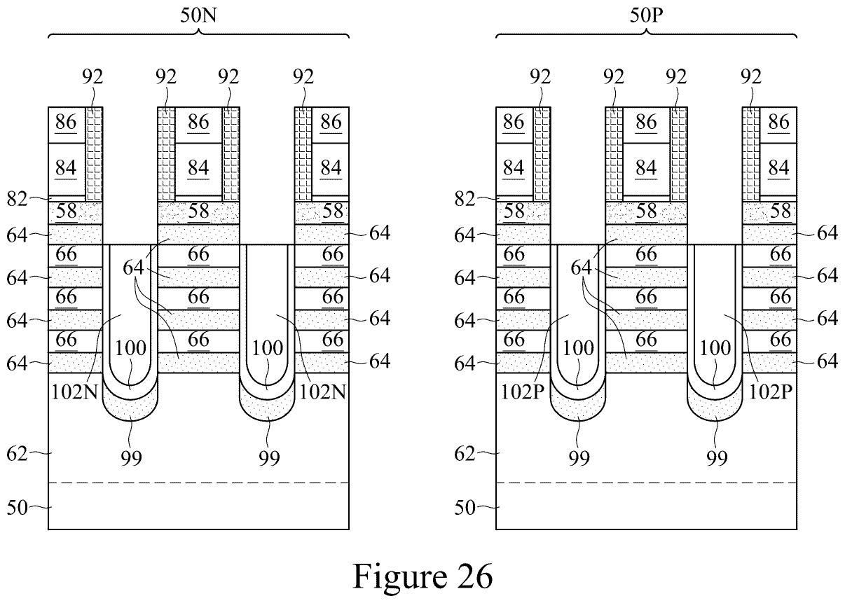

In FIG. 26, sacrificial layers 99, source/drain seed layers 100, and epitaxial source/drain regions 102 are formed in the source/drain recesses, in accordance with some embodiments. The sacrificial layers 99, source/drain seed layers 100, and epitaxial source/drain regions 102 may be formed using similar materials or processes described for FIGS. 12A-14C. For example, sacrificial layers 99 may be deposited in the source/drain recesses 96, then source/drain seed layers 100 may be conformally deposited on the sacrificial layers 99 and over sidewalls of nanostructures 64/66, and then epitaxial source/drain regions 102 may be grown on the source/drain seed layers 100. Epitaxial source/drain regions 102N are formed on the source/drain seed layers 100 in the n-type region 50N and epitaxial source/drain regions 102P are formed on the source/drain seed layers 100 in the p-type region 50P. FIG. 26 shows the source/drain seed layers 100 and epitaxial source/drain layers 102 having top surfaces that are approximately level with top surfaces of the top-most second nanostructures 66, but the source/drain seed layers 100 and epitaxial source/drain layers 102 may protrude above or be recessed from top surfaces of the top-most second nanostructures 66 in other embodiments. For example, in some embodiments, the source/drain seed layers 100 may extend on sidewalls of the top-most first nanostructures 64.

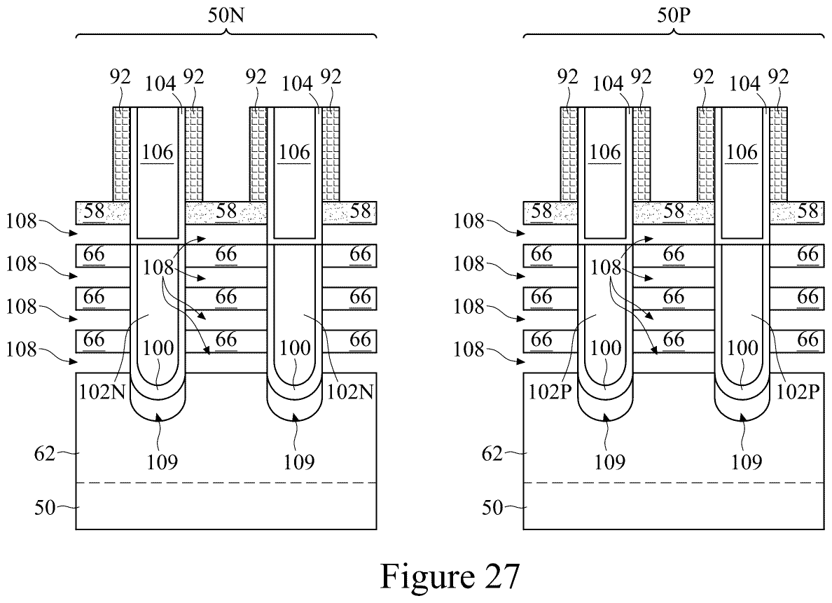

In FIG. 27, an etch process is performed to remove the first nanostructures 64 and the sacrificial layers 99, in accordance with some embodiments. The CESL 104 and the first ILD 106 may also be formed, in some embodiments. The materials and processes may be similar to those described for FIGS. 15A-17C. For example, after forming the first ILD 106, the masks 86 (if present), the dummy gates 84, and the dummy dielectrics 82 may be removed. The first nanostructures 64 and the sacrificial layers 99 are then removed using an etch process that selectively etches the material of the first nanostructures 64 at a faster rate than the second nanostructures 66. Removing the first nanostructures 64 forms openings 108 in regions between the second nanostructures 66, and removing the sacrificial layers 99 forms openings 109 between the source/drain seed layers 100 and the fins 62.

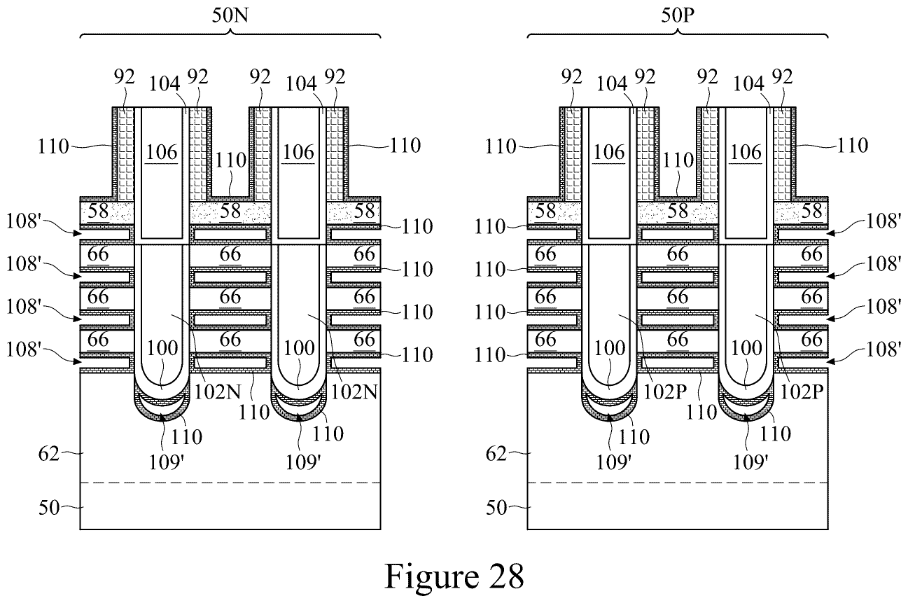

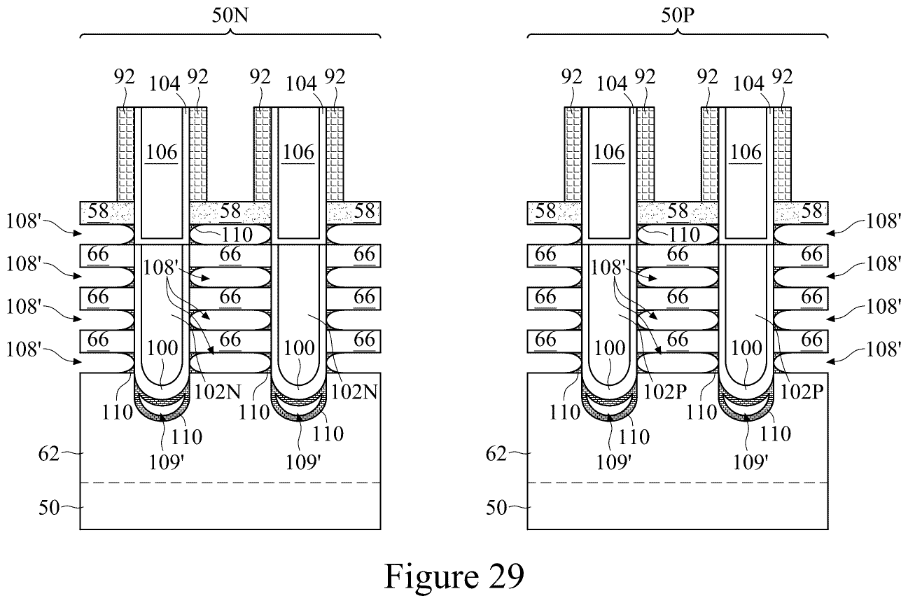

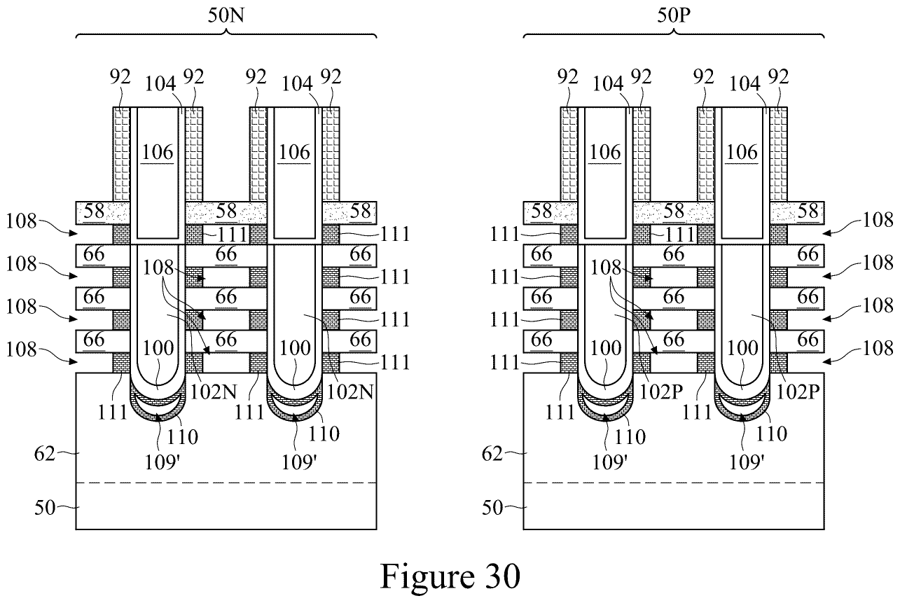

In FIGS. 28-30, multiple deposition and etching cycles are performed to form inner spacers 111 from a spacer material 110, in accordance with some embodiments. FIGS. 28 and 29 illustrate the deposition of the spacer material 110 and the etching of the spacer material 110 according to a first deposition-etching cycle, and FIG. 30 illustrates inner spacers 111 formed after multiple deposition-etching cycles have been performed. The spacer material 110 may be similar to the spacer material 110 described previously for FIGS. 18A-18C, such as silicon oxide or the like. In each deposition-etching cycle, the spacer material 110 may be deposited using a suitable conformal deposition process, such as ALD, CVD, or the like. In each deposition-etching cycle, the spacer material 110 may be etched using a wet etch or a dry etch, which may be isotropic or anisotropic. Forming the inner spacers 111 using multiple deposition-etching cycles can allow for better control over the shape (e.g., sidewall profile) and dimensions of the inner spacers 111. Any suitable number of deposition-etching cycles may be performed, such as one deposition-etching cycle or more than one deposition-etching cycle.

In FIG. 28, the spacer material 110 is conformally deposited during the deposition step in the first deposition-etching cycle. The spacer material 110 is deposited in the openings 108 and in the openings 109. The spacer material 110 may also be conformally deposited on surfaces of the first ILD 70, the fins 62, the hard mask 58, and the gate spacers 92. The spacer material 110 may cover surfaces of the second nanostructures 66 and the source/drain seed layers 100 that were previously exposed by the openings 108. The spacer material 110 may also be conformally deposited on surfaces of the source/drain seed layers 100 and fins 62 in the openings 109. In some embodiments, the spacer material 110 does not completely fill the openings 108 or the openings 109, leaving remaining openings 108′ and openings 109′.

In FIG. 29, the spacer material 110 is etched during the etching step in the first deposition-etching cycle. In the example shown in FIG. 29, the etching step removes portions of the spacer material 110 such that the remaining portions of the spacer material 110 are located in the corners of the openings 108. The particular characteristics (e.g., shape, size, location) of the remaining portions of the spacer material 110 may depend on the etching process used during the etching step. Accordingly, the spacer material 110 may be different than shown after the first deposition-etching cycle is performed.

FIG. 30 illustrates the formation of inner spacers 111 after multiple deposition-etching cycles have been performed, in accordance with some embodiments. The inner spacers 111 are shown as having flat sidewalls, but other sidewall profiles are possible. By controlling the parameters of the deposition steps and the etching steps in the deposition-etching cycles, the inner spacers 111 may be formed having other dimensions or sidewall profiles. In some cases, forming the inner spacers 111 using multiple deposition-etching cycles can form inner spacers 111 having a greater height, which can improve isolation and reduce parasitic capacitance.

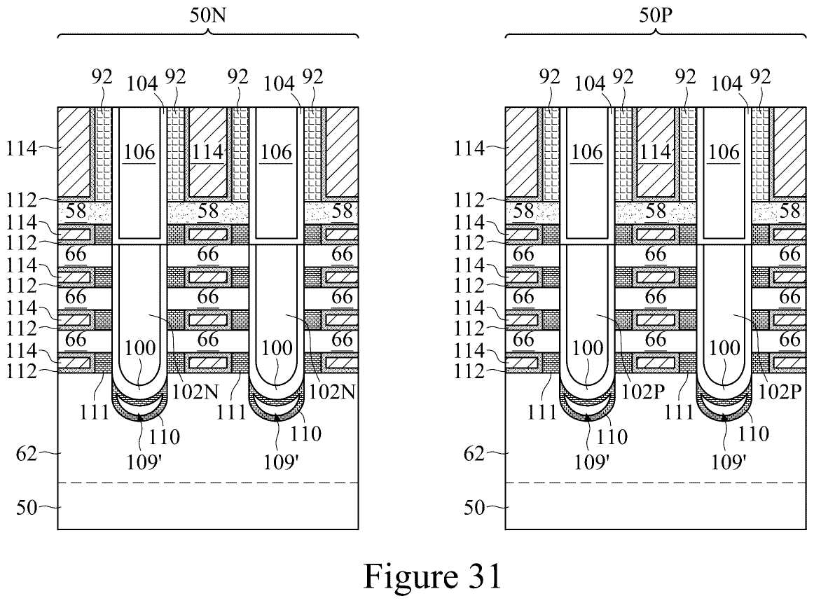

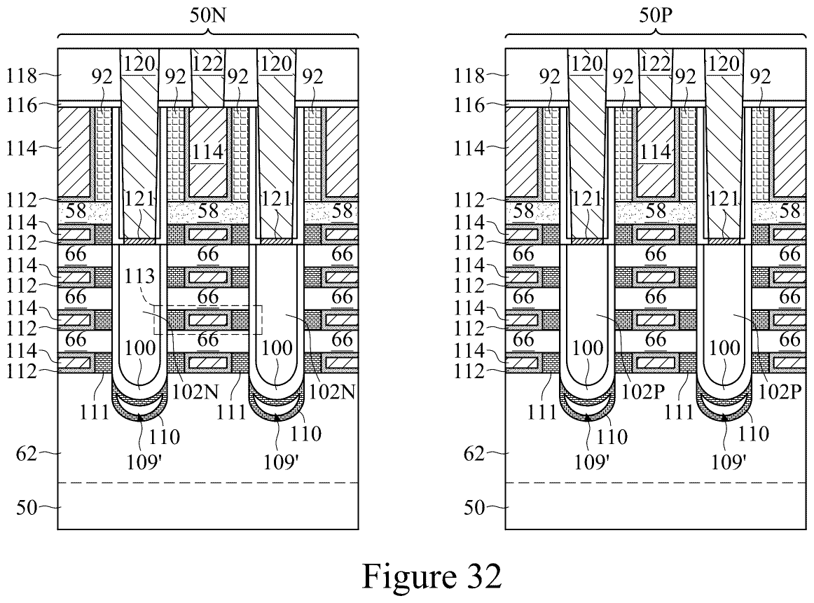

In FIG. 31, gate structures are formed in the openings 108, in accordance with some embodiments. The gate structures may be formed using similar materials or techniques as the gate structures described for FIG. 20A. For example, the gate structures may comprise gate dielectrics 112 and gate electrodes 114. In FIG. 32, gate contacts 122 and source/drain contacts 120 are formed, in accordance with some embodiments. The gate contacts 122 and source/drain contacts 120 may be formed using materials or techniques similar to those described for FIG. 22A. In some embodiments, top surfaces of the epitaxial source/drain regions 102 may be approximately level with or higher than (e.g., protrude above) top surfaces of the top-most nanostructures 66.

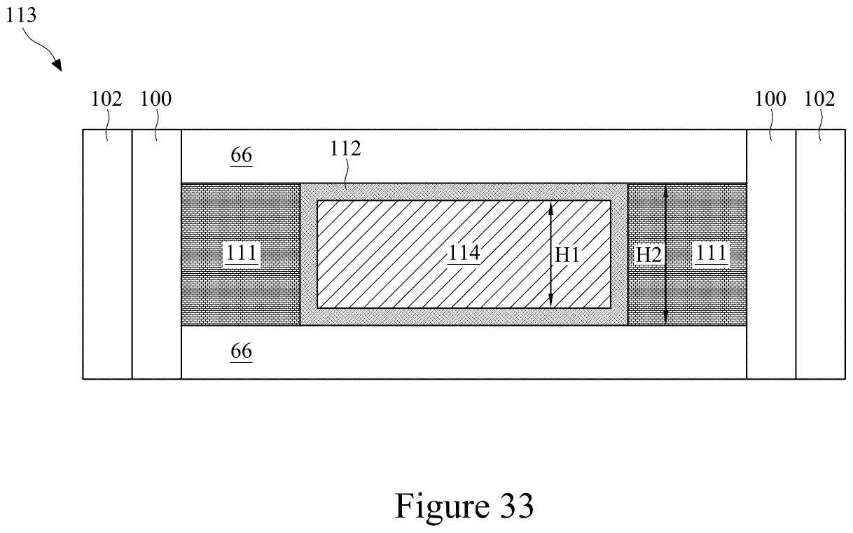

FIG. 33 illustrates a magnified view of a nano-FET, in accordance with some embodiments. The magnified view shown in FIG. 33 may correspond approximately to the region 113 of the n-type region 50N shown in FIG. 32, though FIG. 33 may represent a different region of a nano-FET or a region in the p-type region 50P. FIG. 33 illustrates a non-limiting example of inner spacers 111 and gate structures, in accordance with some embodiments. Other shapes or configurations are possible. In some cases, the shapes or configurations of the gate structures and the inner spacers 111 may be controlled by controlling the various associated etch processes used during manufacture of the nano-FET.

FIG. 33 illustrates a gate structure having a rectangular shape, in accordance with some embodiments. In the embodiment of FIG. 33, the inner spacers 111 have approximately flat sidewalls. In other embodiments, the sidewalls of the inner spacers 111 may be concave, convex, or the like. As shown in FIG. 33, the inner spacers 111 have a height H2 that is greater than a height H1 of the gate electrode 114, though other heights are possible. In some embodiments, the inner spacers 111 may have a width in the range of about 1 nm to about 15 nm, or a height H2 in the range of about 1 nm to about 15 nm. In some cases, these dimensions and relative heights may also apply to other shapes or configurations.

FIG. 34 illustrates nano-FETs, in accordance with some embodiments. The nano-FETs of FIG. 34 are similar to the nano-FETs of FIGS. 22A-22C, except that the hard mask 58 is not present. In some embodiments, the hard mask 58 may be formed but removed e.g., before forming the dummy dielectric layer 72, the dummy gate layer 74, and the mask layer 76. In other embodiments, the hard mask 58 is not formed during manufacture. As shown in FIG. 34, top surfaces of the epitaxial source/drain regions 102 may be approximately level with or below top surfaces of the top-most nanostructures 66. In other embodiments, the epitaxial source/drain regions 102 may be recessed from or may protrude above the top-most nanostructures 66. This and other nano-FETs described herein are examples, and other embodiments may have different configurations or arrangements of layers, structures, or other features.

Embodiments may achieve advantages. By forming the source/drain regions of nano-FETs before forming the inner spacers of the nano-FETs, a continuous source/drain seed layer may be deposited in the source/drain recesses. The source/drain regions may be formed on the source/drain seed layer, which can allow for better quality source/drain regions having fewer defects and improved uniformity. The improvement in uniformity can reduce source/drain region volume, which can reduce the risk of unwanted merging of adjacent source/drain regions and allow for increased device density. Increasing the source/drain region uniformity can also increase the uniformity of device performance. By forming source/drain regions having fewer defects, device operation can be improved. Additionally, the better-quality source/drain regions can impart more channel stress, which can further improve device operation.

In an embodiment, a method includes forming a stack of nanostructures over a substrate; forming a recess in the substrate adjacent the stack of nanostructures, wherein the recess exposes sidewalls of the stack of nanostructures; depositing a continuous semiconductor seed layer in the recess and extending along the sidewalls of the stack of nanostructures; epitaxially growing a source/drain region on the semiconductor seed layer; after epitaxially growing the source/drain region, forming inner spacers between adjacent nanostructures of the stack of nanostructures; and forming a gate structure between adjacent nanostructures of the stack of nanostructures. In an embodiment, the inner spacers contact the semiconductor seed layer. In an embodiment, the semiconductor seed layer includes a doped silicon layer. In an embodiment, forming inner spacer includes performing at least one deposition-etching cycle, wherein each deposition-etching cycle includes: performing a deposition process to deposit a spacer material between adjacent nanostructures of the stack of nanostructures; and performing an etching process to etch a portion of the spacer material. In an embodiment, the deposition process is a conformal deposition process. In an embodiment, the method includes, before depositing the semiconductor seed layer, forming sacrificial spacers between adjacent nanostructures of the stack of nanostructures; and before forming the inner spacers, removing the sacrificial spacers. In an embodiment, the method includes, before depositing the semiconductor seed layer, depositing a sacrificial layer in the recess; and before forming the inner spacers, removing the sacrificial layer. In an embodiment, a height of an inner spacer is smaller than a height of an adjacent portion of the gate structure. In an embodiment, the method includes forming a hard mask over the stack of nanostructures, wherein the gate structure is formed above and below the hard mask.

In an embodiment, a method includes forming a stack of nanostructures over a substrate, wherein the stack of nanostructures includes alternating first nanostructures and second nanostructures, wherein the first nanostructures include a first semiconductor material and the second nanostructures include a second semiconductor material; forming a trench extending through the stack of nanostructures to the substrate; depositing a first semiconductor layer that continuously covers sidewall surfaces of the trench; depositing an epitaxial source/drain region on the first semiconductor layer; removing the second nanostructures; depositing an insulating material on surfaces of the first semiconductor layer opposite the epitaxial source/drain region; and etching the insulating material. In an embodiment, the method includes recessing sidewalls of the second nanostructures; depositing a layer of the first semiconductor material on the recessed sidewalls of the second nanostructures; and depositing a layer of the second semiconductor material on the layer of the first semiconductor material. In an embodiment, removing the second nanostructures also removes the layer of the second semiconductor material. In an embodiment, the method includes depositing the insulating material in the trench between the first semiconductor layer and the substrate. In an embodiment, the first semiconductor material is silicon and the second semiconductor material is silicon germanium. In an embodiment, the method includes forming a hard mask layer on the stack of nanostructures and forming a dummy gate structure on the hard mask layer.

In an embodiment, a device includes nanostructures over a substrate, wherein neighboring nanostructures are vertically separated by insulating spacers and gate structures; a source/drain region over the substrate, wherein the source/drain region includes: a semiconductor layer extending continuously on the first insulating layer, along sidewalls of the nanostructures, and along sidewalls of the insulating spacers; and an epitaxial layer on the continuous semiconductor layer; and an isolation structure under the source/drain region. In an embodiment, the isolation structure seals an air gap beneath the source/drain region. In an embodiment, the insulating spacers protrude into the source/drain region. In an embodiment, the insulating spacers have a height in the range of 1 nm to 15 nm. In an embodiment, the semiconductor layer has a thickness in the range of 0.5 nm to 20 nm.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a stack of nanostructures over a substrate;
forming a recess in the substrate adjacent the stack of nanostructures, wherein the recess exposes sidewalls of the stack of nanostructures;
depositing a continuous semiconductor seed layer in the recess and extending along the sidewalls of the stack of nanostructures;
epitaxially growing a source/drain region on the semiconductor seed layer;
after epitaxially growing the source/drain region, forming inner spacers between adjacent nanostructures of the stack of nanostructures; and
forming a gate structure between adjacent nanostructures of the stack of nanostructures.

2. The method of claim 1, wherein the inner spacers contact the semiconductor seed layer.

3. The method of claim 1, wherein the semiconductor seed layer comprises a doped silicon layer.

4. The method of claim 1, wherein forming inner spacer comprises performing at least one deposition-etching cycle, wherein each deposition-etching cycle comprises:
performing a deposition process to deposit a spacer material between adjacent nanostructures of the stack of nanostructures; and
performing an etching process to etch a portion of the spacer material.

5. The method of claim 4, wherein the deposition process is a conformal deposition process.

6. The method of claim 1 further comprising:
before depositing the semiconductor seed layer, forming sacrificial spacers between adjacent nanostructures of the stack of nanostructures; and
before forming the inner spacers, removing the sacrificial spacers.

7. The method of claim 1 further comprising:
before depositing the semiconductor seed layer, depositing a sacrificial layer in the recess; and
before forming the inner spacers, removing the sacrificial layer.

8. The method of claim 1, wherein a height of an inner spacer is smaller than a height of an adjacent portion of the gate structure.

9. The method of claim 1 further comprising forming a hard mask over the stack of nanostructures, wherein the gate structure is formed above and below the hard mask.

10. A method comprising:
forming a stack of nanostructures over a substrate, wherein the stack of nanostructures comprises alternating first nanostructures and second nanostructures, wherein the first nanostructures comprise a first semiconductor material and the second nanostructures comprise a second semiconductor material;
forming a trench extending through the stack of nanostructures to the substrate;
depositing a first semiconductor layer that continuously covers sidewall surfaces of the trench;
depositing an epitaxial source/drain region on the first semiconductor layer;
removing the second nanostructures;
depositing an insulating material on surfaces of the first semiconductor layer opposite the epitaxial source/drain region; and
etching the insulating material.

11. The method of claim 10 further comprising:
recessing sidewalls of the second nanostructures;
depositing a layer of the first semiconductor material on the recessed sidewalls of the second nanostructures; and
depositing a layer of the second semiconductor material on the layer of the first semiconductor material.

12. The method of claim 11, wherein removing the second nanostructures also removes the layer of the second semiconductor material.

13. The method of claim 10 further comprising depositing the insulating material in the trench between the first semiconductor layer and the substrate.

14. The method of claim 10, wherein the first semiconductor material is silicon and the second semiconductor material is silicon germanium.

15. The method of claim 10 further comprising forming a hard mask layer on the stack of nanostructures and forming a dummy gate structure on the hard mask layer.

16. A device comprising:
a plurality of nanostructures over a substrate, wherein neighboring nanostructures are vertically separated by insulating spacers and gate structures;
a source/drain region over the substrate, wherein the source/drain region comprises:
a semiconductor layer extending continuously on the first insulating layer, along sidewalls of the plurality of nanostructures, and along sidewalls of the insulating spacers; and
an epitaxial layer on the continuous semiconductor layer; and
an isolation structure under the source/drain region.

17. The device of claim 16, wherein the isolation structure seals an air gap beneath the source/drain region.

18. The device of claim 16, wherein the insulating spacers protrude into the source/drain region.

19. The device of claim 16, wherein the insulating spacers have a height in the range of 1 nm to 15 nm.

20. The device of claim 16, wherein the semiconductor layer has a thickness in the range of 0.5 nm to 20 nm.
